(19) United States
(12) Patent Application Publication
(10) Pub. No.: US 2026/0025998 A1
(43) Pub. Date: Jan. 22, 2026

(54) SEMICONDUCTOR STRUCTURE, MANUFACTURING METHOD THEREOF, AND MEMORY SYSTEM

(71) Applicant: Yangtze Memory Technologies Co., Ltd., Wuhan (CN)

(72) Inventors: Tingting ZHAO, Wuhan (CN); Zongliang HUO, Wuhan (CN); Jing GAO, Wuhan (CN); Sizhe LI, Wuhan (CN); Wenbo ZHANG, Wuhan (CN); Zengpeng ZHANG, Wuhan (CN)

(21) Appl. No.: 19/223,660

(22) Filed: May 30, 2025

(30) Foreign Application Priority Data
Jul. 16, 2024 (CN) 202410956444.6

(51) Int. Cl. H10B 43/27; H10B 43/10

(52) U.S. Cl. CPC H10B 43/27; H10B 43/10

(57) ABSTRACT

Semiconductor structures, manufacturing methods thereof and memory systems are provided. An example semiconductor structure includes a first stack structure, a second stack structure, a semiconductor layer, first gate line isolation structures, and second gate line isolation structures. The second stack structure is located on a side of the first stack structure. The semiconductor layer is located between the first stack structure and the second stack structure. The first gate line isolation structure extends through the second stack structure, the semiconductor layer, and the first stack structure along a stacking direction. The second gate line isolation structure extends through the second stack structure and the first stack structure along the stacking direction. The first and second gate line isolation structures extend along a first direction. The second gate line isolation structure is located between adjacent first gate line isolation structures in a second direction intersecting with the first direction.

### CROSS-REFERENCE TO RELATED APPLICATIONS

This application claims the benefit of priority to Chinese Patent Application No. 202410956444.6, filed on Jul. 16, 2024, the disclosure of which is hereby incorporated by reference in its entirety.

### TECHNICAL FIELD

The present disclosure relates to the field of semiconductor technologies, and in particular, to a semiconductor structure, a memory system, and a manufacturing method of the semiconductor structure.

### BACKGROUND

In order to improve the integration level of the semiconductor structure, the number of stacked layers in the semiconductor structure gradually increases. However, a high number of stacked layers results in an increase in planar size of the semiconductor structure and also increases the manufacturing difficulty and manufacturing cost of the semiconductor structure.

### SUMMARY

According to a first aspect, some examples of the present disclosure provide a semiconductor structure. The semiconductor structure comprises a first stack structure, a second stack structure, a semiconductor layer, first gate line isolation structures and second gate line isolation structures. The second stack structure is located on a side of the first stack structure, the semiconductor layer is located between the first stack structure and the second stack structure, the first gate line isolation structure extends through the second stack structure, the semiconductor layer and the first stack structure along a stacking direction of the first stack structure and the second stack structure and extends along a first direction, the second gate line isolation structure extends through the second stack structure and the first stack structure along the stacking direction and extends along the first direction, wherein the second gate line isolation structure is located between adjacent first gate line isolation structures in a second direction intersecting with the first direction.

In an exemplary implementation, in the first direction, a size of the first gate line isolation structure is greater than a size of the second gate line isolation structure.

In an exemplary implementation, the semiconductor structure further comprises a first bit line structure, a first isolation structure, a second bit line structure, and a second isolation structure. The first bit line structure is located on a side of the first stack structure away from the semiconductor layer and comprises a plurality of first bit line portions distributed in the second direction, wherein the first bit line portion extends along the second direction and is located between the first gate line isolation structure and the second gate line isolation structure, or between adjacent second gate line isolation structures. The first isolation structure is located between adjacent first bit line portions. The second bit line structure is located on a side of the second stack structure away from the semiconductor layer and comprises a plurality of second bit line portions distributed in the second direction, wherein the second bit line portion extends along the second direction and is located between the first gate line isolation structure and the second gate line isolation structure, or between adjacent second gate line isolation structures. The second isolation structure is located between adjacent second bit line portions.

In an exemplary implementation, the semiconductor layer extends between adjacent first gate line isolation structures.

In an exemplary implementation, the second gate line isolation structure extends through the semiconductor layer.

In an exemplary implementation, in a plane defined by the first direction and the second direction, the first stack structure and the second stack structure comprise a memory region and a connection region, and the connection region is located on a side of the memory region in the first direction; wherein the first gate line isolation structure extends within the memory region and the connection region, and the second gate line isolation structure extends within the memory region.

In an exemplary implementation, the semiconductor structure further comprises a first staircase structure and a second staircase structure. The first staircase structure is located in the first stack structure and comprises a plurality of first step structures distributed along a circumferential direction. The second staircase structure is located in the second stack structure and comprises a plurality of second step structures distributed along a circumferential direction.

In an exemplary implementation, the first step structure comprises a plurality of first sub-step structures distributed along a radial direction, and the second step structure comprises a plurality of second sub-step structures distributed along a radial direction.

In an exemplary implementation, depths of the plurality of first sub-step structures relative to the semiconductor layer are different from each other, and depths of the plurality of second sub-step structures relative to the semiconductor layer are different from each other.

In an exemplary implementation, in a plane defined by the first direction and the second direction, the first staircase structure comprises a plurality of first step regions distributed along a circumferential direction, the first step structure is located within adjacent first step regions, the second staircase structure comprises a plurality of second step regions distributed along a circumferential direction, and the second step structure is located within adjacent second step regions; wherein a shape of the first step region comprises a sector, and a shape of the second step region comprises a sector.

In an exemplary implementation, the first staircase structure and the second staircase structure are at least partially aligned in the stacking direction of the first stack structure and the second stack structure.

In an exemplary implementation, the semiconductor structure further comprises a connection structure. The connection structure extends along the stacking direction of the first stack structure and the second stack structure, and is connected to one of the first sub-step structures and one of the second sub-step structures.

In an exemplary implementation, the semiconductor structure further comprises a first insulation structure and a second insulation structure. The first insulation structure is located on a side of the first staircase structure away from the semiconductor layer, and the second insulation structure is located on a side of the second staircase structure away from the semiconductor layer. The connection structure comprises a first connection portion and a second connection portion. The first connection portion extends through the first insulation structure and extends to the first staircase structure. The second connection portion extends through the second insulation structure and extends to the second staircase structure.

In an exemplary implementation, the semiconductor structure further comprises a first insulation structure and a second insulation structure. The first insulation structure is located on a side of the first staircase structure close to the semiconductor layer, and the second insulation structure is located on a side of the second staircase structure away from the semiconductor layer. The connection structure extends through the second insulation structure, the second staircase structure, the first insulation structure and the first staircase structure.

In an exemplary implementation, the semiconductor structure further comprises an isolation layer surrounding portions of the connection structure extending through the first staircase structure and the second staircase structure.

In an exemplary implementation, in a plane defined by the first direction and the second direction, a size of a portion of the connection structure extending through the first insulation structure is greater than a size of a portion of the connection structure extending through the first staircase structure; and in a plane defined by the first direction and the second direction, a size of a portion of the connection structure extending through the second insulation structure is greater than a size of a portion of the connection structure extending through the second staircase structure.

In an exemplary implementation, the semiconductor structure further comprises a first surrounding portion and a second surrounding portion. The first surrounding portion surrounds the connection structure and is in contact with the first staircase structure. The second surrounding portion surrounds the connection structure and is in contact with the second staircase structure.

In an exemplary implementation, the first stack structure comprises a first stack portion and a second stack portion distributed along the stacking direction, the first staircase structure is located in the first stack portion, the second stack portion covers the first insulation structure, the connection structure extends through the second stack portion, and the isolation layer surrounds a portion of the connection structure extending through the second stack portion.

In an exemplary implementation, the semiconductor structure further comprises a first insulation layer and a second insulation layer. The first insulation layer is located between the first staircase structure and the first insulation structure, and the second insulation layer is located between the second staircase structure and the second insulation structure.

In an exemplary implementation, the connection structure comprises a plurality of sub-connection structures distributed along the stacking direction, and in a plane defined by the first direction and the second direction, a size of the sub-connection structure along the stacking direction is incremented.

In an exemplary implementation, the semiconductor structure further comprises a first channel structure. The first channel structure extends through the second stack structure, the semiconductor layer, and the first stack structure, and is connected to the first bit line portion and the second bit line portion.

In an exemplary implementation, the semiconductor structure further comprises a second channel structure. The second channel structure extends through the second staircase structure and the first staircase structure.

In an exemplary implementation, the first staircase structure comprises first dielectric layers and first gate layers alternately disposed in the stacking direction, and the second staircase structure comprises second dielectric layers and second gate layers alternately disposed in the stacking direction, wherein the connection structure is connected to one of the first gate layers in the first sub-step structure, and is connected to one of the second gate layers in the second sub-step structure.

In an exemplary implementation, a top layer of the first sub-step structure is the first gate layer, and the first gate layers that are top layers of the plurality of first sub-step structures are different from each other; and a top layer of the second sub-step structure is the second gate layer, and the second gate layers that are top layers of the plurality of second sub-step structures are different from each other.

In an exemplary implementation, the first staircase structure comprises a plurality of first staircase structures, and the first gate layers that are the top layers of the plurality of first sub-step structures in each of the first staircase structures are different from each other; and the second staircase structure comprises a plurality of second staircase structures, and the second gate layers that are the top layers of the plurality of second sub-step structures in each of the second staircase structures are different from each other.

In an exemplary implementation, the first stack structure comprises first dielectric layers and first gate layers alternately disposed in the stacking direction, and the second stack structure comprises second dielectric layers and second gate layers alternately disposed in the stacking direction.

According to a second aspect, some examples of the present disclosure provide a memory system. The memory system comprises a memory and a controller. The memory comprises the semiconductor structure mentioned in any one of above examples. The controller is coupled to the memory and configured to control the memory to store data.

According to a third aspect, some examples of the present disclosure provide a manufacturing method of a semiconductor structure. The manufacturing method of the semiconductor structure comprises: forming a semiconductor layer on a side of a first stack structure; forming a second stack structure on a side of the semiconductor layer away from the first stack structure; forming first gate line isolation structures extending through the second stack structure, the semiconductor layer and the first stack structure along a stacking direction of the first stack structure and the second stack structure; and forming second gate line isolation structures extending through the first stack structure and the second stack structure along the stacking direction, wherein the first gate line isolation structure and the second gate line isolation structure extend along a first direction, and the second gate line isolation structure is located between adjacent first gate line isolation structures in a second direction intersecting with the first direction.

In an exemplary implementation, the manufacturing method may further comprise: forming a first bit line structure on a side of the first stack structure away from the semiconductor layer, wherein the first bit line structure comprises a plurality of first bit line portions distributed in a second direction, wherein the first bit line portion extends along the second direction and is located between the first gate line isolation structure and the second gate line isolation structure, or between adjacent second gate line isolation structures; forming a first isolation structure between adjacent first bit line portions; forming a second bit line structure on a side of the second stack structure away from the semiconductor layer, wherein the second bit line structure comprises a plurality of second bit line portions distributed in the second direction, wherein the second bit line portion extends along the second direction and is located between the first gate line isolation structure and the second gate line isolation structure, or between adjacent second gate line isolation structures; and forming a second isolation structure between adjacent second bit line portions.

In an exemplary implementation, forming the second gate line isolation structures extending through the first stack structure and the second stack structure along the stacking direction comprises: forming the second gate line isolation structures extending through the second stack structure, the semiconductor layer, and the first stack structure along the stacking direction.

In an exemplary implementation, the manufacturing method further comprises: forming a first staircase structure in the first stack structure, wherein the first staircase structure comprises a plurality of first step structures distributed along a circumferential direction; and forming a second staircase structure in the second stack structure, wherein the second staircase structure comprises a plurality of second step structures distributed along a circumferential direction.

In an exemplary implementation, the manufacturing method further comprises: forming a connection structure extending along the stacking direction, wherein the connection structure is connected to one of the first step structures and one of the second step structures.

In an exemplary implementation, the manufacturing method further comprises: forming a first insulation structure on a side of the first staircase structure close to the semiconductor layer; and forming a second insulation structure on a side of the second staircase structure away from the semiconductor layer.

In an exemplary implementation, forming the connection structure extending along the stacking direction of the first stack structure and the second stack structure comprises: forming a connection hole extending through the second insulation structure, the second staircase structure, the first insulation structure and the first staircase structure; forming isolation layers on sidewalls of portions of the first staircase structure and the second staircase structure through which the connection hole extends; and forming the connection structure in the connection hole formed with the isolation layers.

In an exemplary implementation, the first staircase structure comprises first dielectric layers and first gate layers alternately disposed in the stacking direction, and the second staircase structure comprises second dielectric layers and second gate layers alternately disposed in the stacking direction.

In an exemplary implementation, the manufacturing method further comprises: removing portions of the second insulation structure, the second dielectric layer, the first insulation structure, and the first dielectric layer at a periphery of the connection hole; wherein forming the isolation layers on the sidewalls of the portions of the first staircase structure and the second staircase structure through which the connection hole extends comprises: forming initial isolation layers on the sidewalls of the connection hole; and removing portions of the initial isolation layers located on surfaces of the first gate layers in the first staircase structure, and portions of the initial isolation layers located on surfaces of the second gate layers in the second staircase structure, so that the remaining initial isolation layers are configured as the isolation layers.

In an exemplary implementation, the manufacturing method further comprises: forming a first insulation layer between the first staircase structure and the first insulation structure, wherein the first insulation layer is in contact with the first gate layer; forming a second insulation layer between the second staircase structure and the second insulation structure, wherein the second insulation layer is in contact with the second gate layer, and the connection hole extends through the first insulation layer and the second insulation layer; and removing portions of the first insulation layer and the second insulation layer at the periphery of the connection hole to form annular grooves communicated with the connection hole; and filling a conductive material in the annular grooves.

In an exemplary implementation, the method further comprises: forming a first channel structure extending through the second stack structure, the semiconductor layer, and the first stack structure, wherein the first channel structure is connected to the first bit line structure and the second bit line structure.

### BRIEF DESCRIPTION OF DRAWINGS

Other features, objects and advantages of the present disclosure will become more apparent upon reading the detailed description of non-limiting examples made with reference to the following drawings, wherein:

FIG. 1A is a schematic perspective view of a semiconductor structure provided by an example of the present disclosure;

FIG. 1B is a schematic cross-sectional view of a semiconductor structure provided by an example of the present disclosure;

FIG. 1C is a schematic top view of a semiconductor structure provided by an example of the present disclosure;

FIG. 1D is a schematic cross-sectional view of a semiconductor structure taken in another plane provided by an example of the present disclosure;

FIG. 1E is a schematic circuit diagram of a semiconductor structure provided by an example of the present disclosure;

FIG. 2A is a schematic cross-sectional view of a first staircase structure, a second staircase structure, and a connection structure included in a semiconductor structure provided by an example of the present disclosure;

FIG. 2B is a partial enlarged view of region C shown in FIG. 2A;

FIG. 2C is a schematic perspective view of a first staircase structure included in a semiconductor structure provided by an example of the present disclosure;

FIG. 3A to FIG. 3E are schematic top views of a first staircase structure provided by an example of the present disclosure;

FIG. 4 is a schematic cross-sectional view of a first staircase structure, a second staircase structure, and a connection structure included in a semiconductor structure provided by another example of the present disclosure;

FIG. 5 is a schematic cross-sectional view of a first staircase structure, a second staircase structure, and a connection structure included in a semiconductor structure provided by yet another example of the present disclosure;

FIG. 6A is a schematic perspective view of a semiconductor structure provided by another example of the present disclosure;

FIG. 6B is a schematic cross-sectional view of a semiconductor structure provided by another example of the present disclosure;

FIG. 7 is a schematic flowchart of a manufacturing method of a semiconductor structure provided by an example of the present disclosure;

FIG. 8A to FIG. 8G are schematic cross-sectional views of a semiconductor structure in a manufacturing process provided by an example of the present disclosure;

FIG. 9A to FIG. 9F are schematic cross-sectional views of a semiconductor structure in a manufacturing process provided by another example of the present disclosure;

FIG. 10 is a schematic block diagram of a system having a memory system provided by an example of the present disclosure; and

FIG. 11A and FIG. 11B are schematic block diagrams of a memory system provided by an example of the present disclosure.

### DETAILED DESCRIPTION

In order to better understand the present disclosure, various aspects of the present disclosure will be described in more detail with reference to the accompanying drawings. It should be understood that these detailed descriptions are merely descriptions of exemplary implementations of the present disclosure, and are not intended to limit the scope of the present disclosure in any manner. Throughout the description, like reference numbers refer to like elements. The expression “and/or” comprises any and all combinations of one or more of the associated listed items.

It should be noted that in this specification, the expressions of the first, second, third, etc. are merely used to distinguish one feature from another feature, and do not represent any limitation on the feature, and in particular, do not represent any order. Therefore, a first stack structure discussed in the present disclosure may also be referred to as a second stack structure, and a first gate line isolation structure discussed in the present disclosure may also be referred to as a second gate line isolation structure, or vice versa, without departing from the teachings of the present disclosure.

In the drawings, thickness, size, and shape of components have been slightly adjusted for ease of illustration. The drawings are merely examples and are not drawn to scale. As used herein, the terms “substantially,” “about,” and the like are used as the terms that represent approximation, and are not used as terms that represent the extent, and are intended to illustrate inherent deviations in measured values or calculated values to be recognized by those of ordinary skill in the art.

It should also be understood that expressions such as “comprising,” “comprise,” “having,” “including,” and/or “include,” and the like, are open and not closed expressions in this specification that indicate the presence of stated features, elements, and/or components, but do not preclude the presence of one or more other features, elements, components, and/or combinations thereof. Furthermore, when expressions such as “at least one of” appear before the list of listed features, it embellishes the entire column of features rather than just embellishing individual elements in the list. In addition, when describing implementations of the present disclosure, “may” is used to mean “one or more implementations of the present disclosure”. Also, the term “exemplary” is intended to refer to an example or illustration.

Unless otherwise defined, all wording (comprising engineering terms and scientific and technological terms) used herein have the same meaning as those of ordinary skill in the art to which the present disclosure belongs. It should also be understood that unless explicitly stated in the present disclosure, words defined in a common dictionary should be interpreted as having a meaning that is consistent with their meaning in the context of the related art, and should not be interpreted in an idealized or overly formal sense.

It should be noted that, in the case of no conflict, implementations and features in the implementations of the present disclosure may be combined with each other. In addition, unless expressly defined or contradicted with context, the specific steps comprised in the methods described in the present disclosure need not be limited to the recited order, but may be performed in any order or in parallel.

Furthermore, “connected” or “coupled”, when used in the present disclosure, may represent direct or indirect contact between respective components, unless expressly otherwise defined or derivable from the context.

Hereinafter, the present disclosure will be described in detail with reference to the accompanying drawings and in combination with the examples.

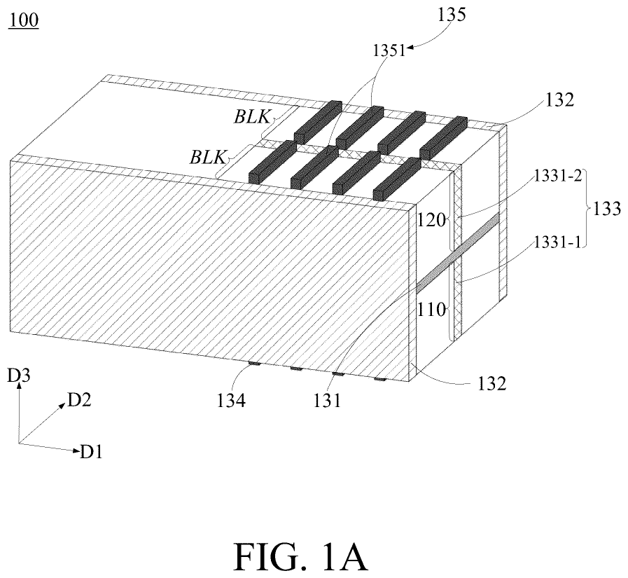

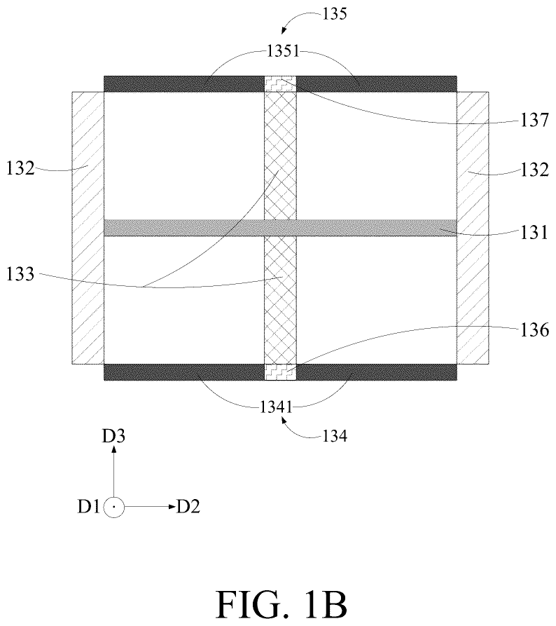

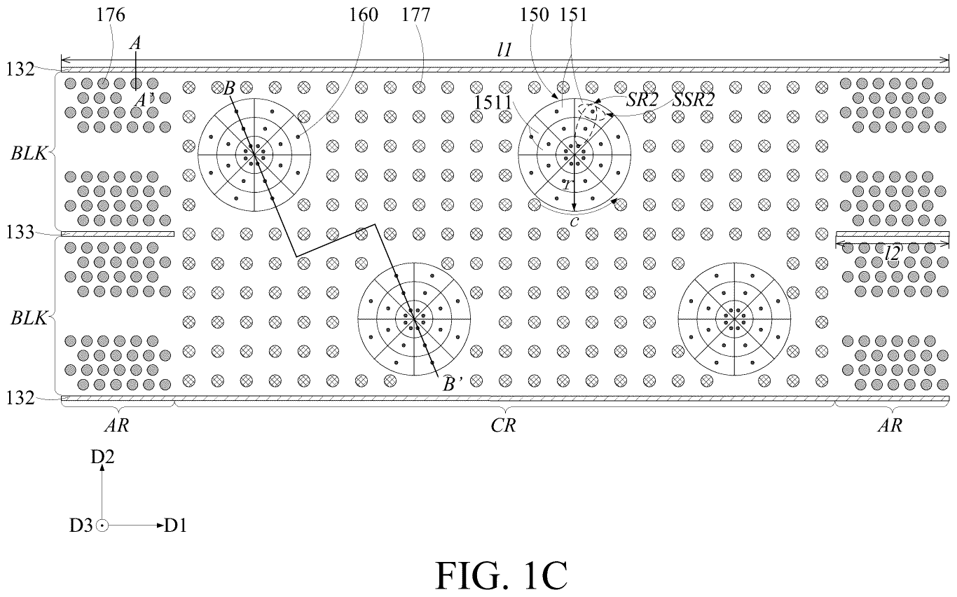

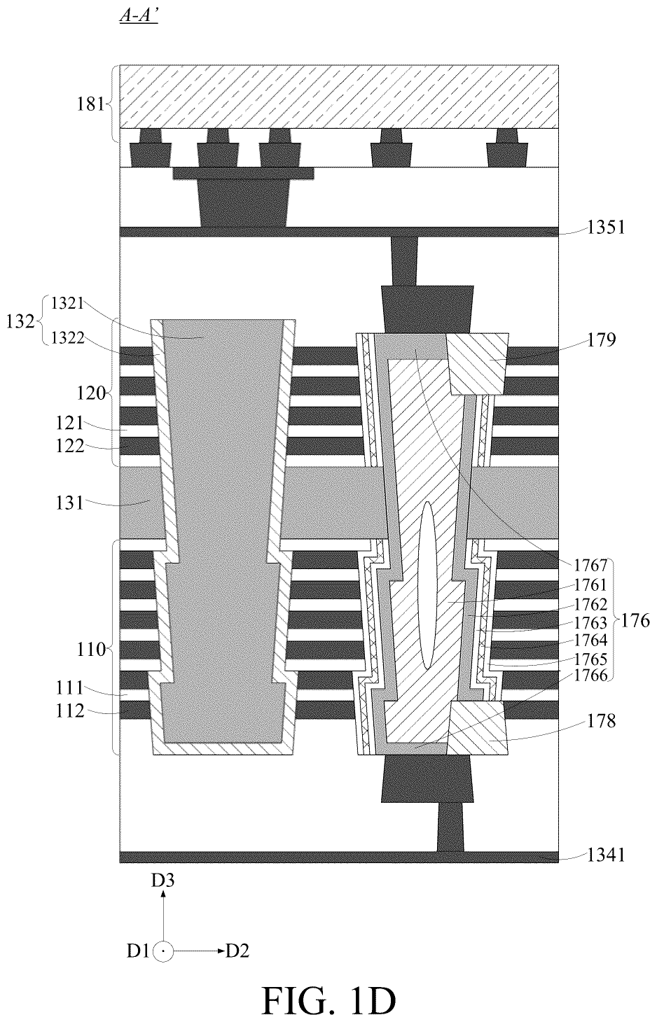

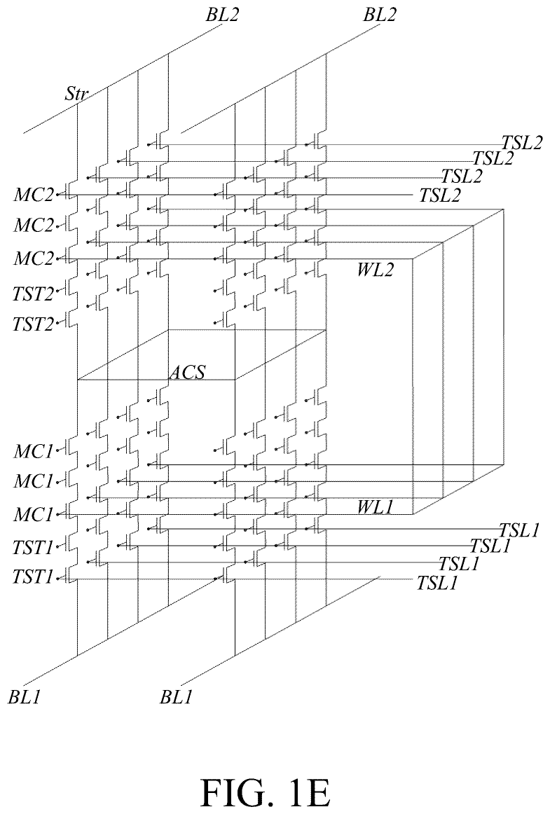

Some examples of the present disclosure provide a semiconductor structure. FIG. 1A is a schematic perspective view of a semiconductor structure provided by an example of the present disclosure. FIG. 1B is a schematic cross-sectional view of a semiconductor structure provided by an example of the present disclosure. FIG. IC is a schematic top view of a semiconductor structure provided by an example of the present disclosure. FIG. 1D is a schematic cross-sectional view of a semiconductor structure taken in another plane provided by an example of the present disclosure. FIG. 1E is a schematic circuit diagram of a semiconductor structure provided by an example of the present disclosure. For example, FIG. 1D may be a schematic cross-sectional view of a semiconductor structure taken along line A-A′ shown in FIG. IC.

It should be noted that, the numbers and sizes of components in the foregoing drawings are merely illustrative, and may be used to represent positional relationship between components, and do not represent actual corresponding relationship of components in the drawings. In addition, D1 direction, D2 direction and D3 direction in the drawings show the spatial relationship of various components in the semiconductor structure. For example, the D3 direction may be a stacking direction of a first stack structure and a second stack structure, and the D1 direction and the D2 direction may be two directions intersecting (e.g., perpendicular) to each other in a plane intersecting (e.g., perpendicular) to the stacking direction. For example, the D1 direction may be an extension direction of a first gate line isolation structure (or a second gate line isolation structure). The D2 direction may be an extension direction of a first bit line structure (or a second bit line structure). The same concept will be employed throughout the present disclosure to describe the spatial relationship of various components in the semiconductor structure.

As shown in FIG. 1A to FIG. 1D, the semiconductor structure 100 may comprise a first stack structure 110, a second stack structure 120, a semiconductor layer 131, a first gate line isolation structure 132, and a second gate line isolation structure 133. The second stack structure 120 may be located on a side of the first stack structure 110. The semiconductor layer 131 may be located between the first stack structure 110 and the second stack structure 120. The first gate line isolation structure 132 may extend through the second stack structure 120, the semiconductor layer 131, and the first stack structure 110 along the D3 direction, and extend along the D1 direction. The second gate line isolation structure 133 may extend through the second stack structure 120 and the first stack structure 110 along the D3 direction, and may extend along the D1 direction. The second gate line isolation structures 133 may be located between adjacent first gate line isolation structures 132 in the D2 direction.

According to the semiconductor structure 100 provided by the above example, the semiconductor layer 131 is disposed between the first stack structure 110 and the second stack structure 120, which can break the limitation on the number of stacked layers and help to improve the unit memory density. Each of the first gate line isolation structure 132 and the second gate line isolation structure 133 may be configured to divide the first stack structure 110 and the second stack structure 120 into memory blocks, which is beneficial to reducing the control difficulty of the semiconductor structure 100 and reducing planar size of the semiconductor structure 100.

In some implementations, as shown in FIGS. 1A-1D, from the D3 direction, the stacked first stack structure 110 and the second stack structure 120 may comprise a memory region AR and a connection region CR. For example, from the D3 direction, the memory regions AR of the first stack structure 110 and the second stack structure 120 substantially coincide, and the connection regions CR of the first stack structure 110 and the second stack structure 120 substantially coincide. In some examples, the two memory regions AR may be located on two opposite sides of one connection region CR in the D1 direction. In other examples, the two connection regions CR may be located on opposite sides of one memory region AR in the D1 direction (not shown).

In some implementations, the first stack structure 110 may comprise a first dielectric layer 111 and a first gate layer 112 alternately disposed in the D3 direction. For example, the outermost layer of the first stack structure 110 in the D3 direction may be the first dielectric layer 111. The number of the first stack pairs formed by the first dielectric layer 111 and the first gate layer 112 may comprise 32, 64, 128, 258 and more, which is not specifically limited in the present disclosure. For example, the first dielectric layer 111 and the first gate layer 112 may extend within the memory region AR and at least a portion of the connection region CR.

In some implementations, a material of the first dielectric layer 111 may comprise one or more of silicon oxide, silicon nitride, silicon oxynitride, or any other suitable insulation material. For example, the material of the first dielectric layer 111 may be silicon oxide.

In some implementations, a material of the first gate layer 112 may comprise one or more of titanium, titanium nitride, tantalum, tantalum nitride, polysilicon, amorphous silicon, tungsten, molybdenum, copper, aluminum, ruthenium, metal silicide, or any other suitable conductive material. In some examples, the first gate layer 112 may be made of a single conductive material. In other examples, the first gate layer 112 may comprise a first metal layer and a first adhesive layer (not shown) covering at least a portion of a surface of the first metal layer. For example, a material of the first metal layer may comprise one or more of tungsten, molybdenum, copper, aluminum, ruthenium, or any other suitable metal material. A material of the first adhesive layer may comprise one or more of titanium, titanium nitride, tantalum, tantalum nitride, or any other suitable adhesive material. Optionally, at least a portion of a surface of the first adhesive layer may be covered with a first high dielectric constant layer (not shown). A material of the first high dielectric constant layer may comprise, but is not limited to, aluminum oxide, titanium oxide, tantalum oxide, hafnium oxide, and the like.

In some implementations, the second stack structure 120 may comprise a second dielectric layer 121 and a second gate layer 122 alternately disposed in the D3 direction. For example, the outermost layer of the second stack structure 120 in the D3 direction may be the second dielectric layer 121. The number of the second stack pairs formed by the second dielectric layer 121 and the second gate layer 122 may comprise 32, 64, 128, 258 and more, which is not specifically limited in the present disclosure. It should be noted that the number of the first stack pairs formed by the second dielectric layer 121 and the first gate layer 112 is the same as or different from the number of the second stack pairs formed by the second dielectric layer 121 and the second gate layer 122, which is not specifically limited in the present disclosure. For example, the second dielectric layer 121 and the second gate layer 122 extend within the memory region AR and at least a portion of the connection region CR.

In some implementations, a material of the second dielectric layer 121 may comprise one or more of silicon oxide, silicon nitride, silicon oxynitride, or any other suitable insulation material. For example, the material of the second dielectric layer 121 may be silicon oxide.

In some implementations, a material of the second gate layer 122 may comprise one or more of titanium, titanium nitride, tantalum, tantalum nitride, polysilicon, amorphous silicon, tungsten, molybdenum, copper, aluminum, ruthenium, metal silicide, or any other suitable conductive material. In some examples, the second gate layer 122 may be made of a single conductive material. In other examples, the second gate layer 122 may comprise a second metal layer and a second adhesive layer (not shown) covering at least a portion of a surface of the second metal layer. For example, a material of the second metal layer may comprise one or more of tungsten, molybdenum, copper, aluminum, ruthenium, or any other suitable metal material. A material of the second adhesive layer may comprise one or more of titanium, titanium nitride, tantalum, tantalum nitride, or any other suitable adhesive material. Optionally, at least a portion of a surface of the second adhesive layer may be covered with a second high dielectric constant layer (not shown). A material of the second high dielectric constant layer may comprise, but is not limited to, aluminum oxide, titanium oxide, tantalum oxide, hafnium oxide, and the like.

In some implementations, the semiconductor layer 131 may extend within the memory region AR and the connection region CR. In other implementations, the semiconductor layer 131 may extend within the memory region AR without extending within the connection region CR. For example, a portion of the semiconductor layer 131 located within the connection region CR may be replaced by an insulation material layer (not shown). A material of the semiconductor layer 131 may comprise one or more of monocrystalline silicon, polysilicon, amorphous silicon, germanium, silicon germanium, a metal oxide semiconductor, or any other suitable semiconductor material. For example, the material of the semiconductor layer 131 may be polysilicon. The semiconductor layer 131 (e.g., a portion located within the memory region AR) may be used as a common source.

In some implementations, the first gate line isolation structure 132 may continuously extend in the memory region AR and the connection region CR along the D1 direction. For example, a portion of the first gate line isolation structure 132 located in the memory region AR may extend through the second stack structure 120, the semiconductor layer 131, and the first stack structure 110 along the D3 direction. A portion of the first gate line isolation structure 132 located in the connection region CR may extend through the second stack structure 120, the semiconductor layer 131 (or the insulation material layer), and the first stack structure 110 along the D3 direction. A plurality of first gate line isolation structures 132 may be arranged at intervals in the D2 direction. For example, the first gate layer 112, the second gate layer 122, and the semiconductor layer 131 located on two opposite sides of the first gate line isolation structure 132 in the D2 direction are electrically isolated.

In some implementations, the first gate line isolation structure 132 may comprise a first polysilicon body 1321 and a first oxide layer 1322. The first polysilicon body 1321 may continuously extend within the memory region AR and the connection region CR along the D1 direction. For example, a portion of the first polysilicon body 1321 located in the memory region AR may sequentially extend through the second stack structure 120, the semiconductor layer 131, and the first stack structure 110 along the D3 direction. A portion of the first polysilicon body 1321 located in the connection region CR may sequentially extend through the second stack structure 120, the semiconductor layer 131 (or the insulation material layer), and the first stack structure 110 along the D3 direction. The first oxide layer 1322 may be located on opposite sidewalls of the first polysilicon body 1321 in the D2 direction, and the first polysilicon body 1321 is located on an end surface of the first stack structure 110. For example, a material of the first oxide layer 1322 may comprise silicon oxide. The first gate line isolation structure 132 is made of the above two materials, which helps to save cost and balance stress. In other implementations, the first gate line isolation structure 132 may be made of a single insulation material, which is not limited in the present disclosure.

In some implementations, the second gate line isolation structure 133 may extend continuously within the memory region AR along the D1 direction. For example, the second gate line isolation structure 133 may comprise two second gate line isolation portions 1331-1 and 1331-2 separated from each other. One second gate line isolation portion 1331-1 may extend through the first stack structure 110, and the other second gate line isolation portion 1331-2 may extend through the second stack structure 120. For example, the semiconductor layer 131 (or the semiconductor layer 131 and the insulation material layer) may extend (e.g., continuously) between adjacent first gate line isolation structures 132. The first gate layers 112 located on two opposite sides of the second gate line isolation portion 1331-1 in the D2 direction are electrically isolated, and the second gate layers 122 located on two opposite sides of the second gate line isolation portion 1331-2 in the D2 direction are electrically isolated.

In some implementations, the second gate line isolation structure 133 (e.g., the second gate line isolation portions 1331-1, 1331-2) may comprise a second polysilicon body and a second oxide layer. The second polysilicon body may extend continuously within the memory region AR along the D1 direction. For example, the second polysilicon body in the second gate line isolation portion 1331-1 may extend through the first stack structure 110 along the D3 direction, and the second oxide layer in the second gate line isolation portion 1331-1 may be located on opposite sidewalls of the second polysilicon body in the D2 direction and an end surface of the second polysilicon body away from the semiconductor layer 131. The second polysilicon body in the second gate line isolation portion 1331-2 may extend through the second stack structure 120 along the D3 direction, and the second oxide layer in the second gate line isolation portion 1331-2 may be located on opposite sidewalls of the second polysilicon body in the D2 direction and an end surface of the second polysilicon body towards the semiconductor layer 131. For example, a material of the second oxide layer may comprise silicon oxide. The second gate line isolation structure 133 is made of the above two materials, which helps to save cost and balance stress. In other implementations, the second gate line isolation structure 133 (for example, the at least one second gate line isolation portion 1331-1, 1331-2) may be made of a single insulation material, which is not limited in the present disclosure.

In some implementations, in a case where two memory regions AR are located on two opposite sides of one connection region CR in the D1 direction, a group of (i.e., two) second gate line isolation structures 133 may be respectively located in the two memory regions AR, and the group of second gate line isolation structures 133 may be at least partially aligned in the D1 direction. In other words, the group of second gate line isolation structures 133 may extend substantially collinearly in the D1 direction. One or more groups of second gate line isolation structures 133 may be arranged at intervals between adjacent first gate line isolation structures 132 in the D2 direction. In some other implementations, in a case where two connection regions CR are located on two opposite sides of one memory region AR in the D1 direction, one or more second gate line isolation structures 133 may be arranged at intervals between the adjacent first gate line isolation structures 132 in the D2 direction.

In some implementations, in the D1 direction, a size of the first gate line isolation structure 132 may be greater than a size of the second gate line isolation structure 133. For example, in a case where two memory regions AR are located on two opposite sides of one connection region CR in the D1 direction, in the D1 direction, a size 11 of the first gate line isolation structure 132 is greater than a size 12 of each of the group of second gate line isolation structures 133.

In some implementations, in a case where one group of (or one) second gate line isolation structures 133 is located between two adjacent first gate line isolation structures 132 in the D2 direction, a portion of a portion of the first stack structure 110 and the second stack structure 120 located in the memory region AR between the first gate line isolation structure 132 and the second gate line isolation structure 133 may be referred to as a memory block BLK. In some other implementations, in a case where a plurality of groups of (or a plurality of) second gate line isolation structures 133 are located between two adjacent first gate line isolation structures 132 in the D2 direction, in addition to the division manner of the memory block BLK, a portion of the portion of the first stack structure 110 and the second stack structure 120 located in the memory region AR between adjacent one group of (or one) second gate line isolation structures 133 may also be referred to as a memory block BLK (not shown).

In some implementations, the semiconductor structure 100 may further comprise a first bit line structure 134 and a first isolation structure 136. The first bit line structure 134 may be located on a side of the first stack structure 110 away from the semiconductor layer 131. The first bit line structure 134 may comprise a plurality of first bit line portions 1341 distributed in a D2 direction, and each first bit line portion 1341 may extend along the D2 direction. The first bit line portion 1341 may be located between the first gate line isolation structure 132 and the second gate line isolation structure 133, or between adjacent second gate line isolation structures 133. The first isolation structure 136 may be located between adjacent first bit line portions 1341. For example, the plurality of first bit line portions 1341 in one first bit line structure 134 extend substantially collinearly in the D2 direction. A plurality of first bit line structures 134 may be arranged at intervals in the D1 direction and may be located within the memory region AR. For another example, the first isolation structure 136 may also be located between adjacent first bit line structures 134 in the D1 direction. In the D3 direction, sizes of the first isolation structure 136 and the first bit line structure 134 may be substantially the same, and the first bit line structure 134 may be embedded in the first isolation structure 136.

In some implementations, a material of the first bit line structure 134 may comprise one or more of titanium, titanium nitride, tantalum, tantalum nitride, polysilicon, amorphous silicon, tungsten, molybdenum, copper, aluminum, ruthenium, metal silicide, or any other suitable conductive material. A material of the first isolation structure 136 may comprise one or more of silicon oxide, silicon nitride, silicon oxynitride, or any other suitable insulation material. For example, the material of the first bit line structure 134 may be tungsten, and the material of the first isolation structure 136 may be silicon oxide.

In some implementations, the semiconductor structure 100 may further comprise a second bit line structure 135 and a second isolation structure 137. The second bit line structure 135 may be located on a side of the second stack structure 120 away from the semiconductor layer 131. The second bit line structure 135 may comprise a plurality of second bit line portions 1351 distributed in the D2 direction, and each second bit line portion 1351 may extend in the D2 direction. The second bit line portion 1351 may be located between the first gate line isolation structure 132 and the second gate line isolation structure 133, or between adjacent second gate line isolation structures 133. The second isolation structure 137 may be located between adjacent second bit line portions 1351. For example, the plurality of second bit line portions 1351 in one second bit line structure 135 extend substantially collinearly in the D2 direction. A plurality of second bit line structures 135 may be arranged at intervals in the D1 direction and may be located within the memory region AR. For another example, the second isolation structure 137 may also be located between adjacent second bit line structures 135 in the D1 direction. In the D3 direction, sizes of the second isolation structure 137 and the second bit line structure 135 may be substantially the same, and the second bit line structure 135 may be embedded in the second isolation structure 137.

In some implementations, a material of the second bit line structure 135 may also comprise one or more of titanium, titanium nitride, tantalum, tantalum nitride, polysilicon, amorphous silicon, tungsten, molybdenum, copper, aluminum, ruthenium, metal silicide, or any other suitable conductive material. A material of the second isolation structure 137 may comprise one or more of silicon oxide, silicon nitride, silicon oxynitride, or any other suitable insulation material. For example, the material of the second bit line structure 135 may be tungsten, and the material of the second isolation structure 137 may be silicon oxide.

In some implementations, the first bit line structure 134 and the second bit line structure 135 are substantially aligned in the D3 direction. For example, from the D3 direction, the first bit line structure 134 and the second bit line structure 135 may substantially coincide.

In the above implementations, two or more memory blocks BLK may share the semiconductor layer 131, and the first bit line portion 1341 and the second bit line portion 1351 may individually control one memory block BLK. The two or more memory blocks BLK may share the connection region CR to reduce the planar size of the connection region CR.

In some implementations, the semiconductor structure 100 may further comprise a first channel structure 176. The first channel structure 176 may extend through the second stack structure 120, the semiconductor layer 131, and the first stack structure 110, and may be connected to the first bit line portion 1341 and the second bit line portion 1351. For example, the first channel structure 176 may be substantially columnar. The first channel structure 176 may comprise a first insulating pillar 1761, a first channel layer 1762, a first tunneling layer 1763, a first charge trapping layer 1764, and a first blocking layer 1765. The first insulating pillar 1761 may extend in the first stack structure 110, the semiconductor layer 131, and the second stack structure 120 along the D3 direction. The first channel layer 1762 may surround the first insulating pillars 1761. The first tunneling layer 1763 may surround a portion of the first channel layer 1762 extending through the first stack structure 110 and the second stack structure 120. The first charge trapping layer 1764 may surround the first tunneling layer 1763. The first blocking layer 1765 may surround the first charge trapping layer 1764. Thus, the semiconductor layer 131 may directly surround the first channel layer 1762. In other words, the semiconductor layer 131 may be in contact with the first channel layer 1762. Optionally, the first channel structure 176 may further comprise a first channel plug 1766 and a second channel plug 1767. The first channel plug 1766 and the second channel plug 1767 may be respectively located at two ends of the first insulating pillar 1761 in the D3 direction, and are in contact with the first channel layer 1762. The first channel plug 1766 may be connected to the first bit line portion 1341 (e.g., through an interconnect line and/or an interconnect channel), and the second channel plug 1767 may be connected to the second bit line portion 1351 (e.g., through an interconnect line and/or an interconnect channel). In this implementation, the semiconductor layer 131 is connected to the middle of the first channel structure 176, the first bit line portion 1341 and the second bit line portion 1351 are respectively connected to two ends of the first channel structure 176, which can reduce a channel length of the first channel structure 176 and help to improve conduction current Ion.

In some implementations, a material of the first insulating pillar 1761 may comprise one or more of silicon oxide, silicon nitride, silicon oxynitride, or any other suitable insulation material. For example, the material of the first insulating pillar 1761 may be silicon oxide. A material of the first channel layer 1762 may comprise one or more of monocrystalline silicon, polysilicon, amorphous silicon, germanium, germanium silicon, a metal oxide semiconductor (e.g., indium gallium zinc oxide), or any other suitable semiconductor material. For example, the material of the first channel layer 1762 may be polysilicon. A materials of the first tunneling layer 1763, the first charge trapping layer 1764, and the first blocking layer 1765 may sequentially comprise silicon oxide, silicon nitride, and silicon oxide. Materials of the first channel plug 1766 and the second channel plug 1767 may be the same as the material of the first channel layer 1762. In this case, there is no obvious interface among the three, and they can form an integrated structure.

In some implementations, there may be a plurality of first channel structures 176. As shown in FIG. 1C, the plurality of first channel structures 176 may be located in the memory area AR, and may be arranged in an array in the D1 direction and the D2 direction. The first channel structure 176 may be configured to implement a storage function.

In some implementations, the semiconductor structure 100 may further comprise a first select gate cut line structure 178. The first select gate cut line structure 178 may extend through several first gate layers 112 from a side of the first stack structure 110 away from the semiconductor layer 131, and may for example extend through a portion of the first channel structure 176. For example, the number of the first gate layers 112 through which the first select gate cut line structure 178 extends may be 1 to 5. The first select gate cut line structure 178 may also extend along the D1 direction (e.g., within the memory region AR). For example, a plurality of first select gate cut line structures 178 may be arranged at intervals along the D2 direction. A material of the first select gate cut line structure 178 may comprise one or more of silicon oxide, silicon nitride, silicon oxynitride, or any other suitable insulation material. For example, the material of the first select gate cut line structure 178 may be silicon oxide.

In some implementations, the semiconductor structure 100 may further comprise a second select gate cut structure 179. The second select gate cut line structure 179 may extend through several second gate layers 122 from a side of the second stack structure 120 away from the semiconductor layer 131, and may for example extend through a portion of the first channel structure 176. For example, the number of the second gate layers 122 through which the second select gate cut line structure 179 extends may be 1 to 5. The second select gate cut line structure 179 may also extend along the D1 direction (e.g., within the memory region AR). For example, a plurality of second select gate cut line structures 179 may be arranged at intervals along the D2 direction. A material of the second select gate cut line structure 179 may comprise one or more of silicon oxide, silicon nitride, silicon oxynitride, or any other suitable insulation material. For example, the material of the second select gate cut line structure 179 may be silicon oxide.

In some implementations, as shown in FIGS. 1D and 1E, a portion of the first channel structure 176 surrounded by one first gate layer 112 through which the first select gate cut line structure 178 extends and a portion of this first gate layer 112 constitute one first select transistor TST1. Other portions of this first gate layer 112 may serve as a first select line TSL1. A portion of the first channel structure 176 surrounded by one of the other first gate layers 112 and a portion of the one first gate layer 112 constitute one first memory cell MC1. Other portions of the one first gate layer 112 may serve as a first word line WL1.

A portion of the first channel structure 176 surrounded by one second gate layer 122 through which the second select gate cut line structure 179 extends and a portion of this second gate layer 122 constitutes one second select transistor TST2. Other portions of this second gate layer 122 may serve as a second select line TSL2. A portion of the first channel structure 176 surrounded by one of the other second gate layers 122 and a portion of the one second gate layer 122 constitute one second memory cell MC2. Other portions of the one second gate layer 122 may serve as a second word line WL2. For example, one first word line WL1 and one second word line WL2 may be connected to each other by a connection structure described in detail below.

A plurality of memory cells (e.g., the first memory cell MC1 and the second memory cell MC2), at least one first select transistor TST1, and at least one second select transistor TST2 are arranged in series along the extending direction (e.g., D3 direction) of the first channel structure 176 to form a memory string Str and share the first channel layer 1762. Two ends of the memory string Str are respectively connected to bit lines BL1 (corresponding to the first bit line portion 1341) and BL2 (corresponding to the second bit line portion 1351), and a common source line ACS (corresponding to the semiconductor layer 131) is connected between the first memory cell MC1 and the second memory cell MC2 in the memory string Str.

In some implementations, the semiconductor structure 100 may further comprise a peripheral circuit structure 181. For example, the peripheral circuit structure 181 may be located on a side of the second stack structure 120 away from the semiconductor layer 131. In other implementations, the peripheral circuit structure 181 may be located on a side (not shown) of the first stack structure 110 away from the semiconductor layer 131. The peripheral circuit structure 181 may comprise any suitable digital, analog, and/or mixed-signal peripheral circuit for controlling the operation of a memory cell array (e.g., a memory cell array composed of first memory cells MC1 and second memory cells MC2). For example, the peripheral circuit may comprise one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any portion (e.g., sub-circuit) of the above functional circuit, or any active or passive component (e.g., transistor, diode, resistor, or capacitor) of a circuit.

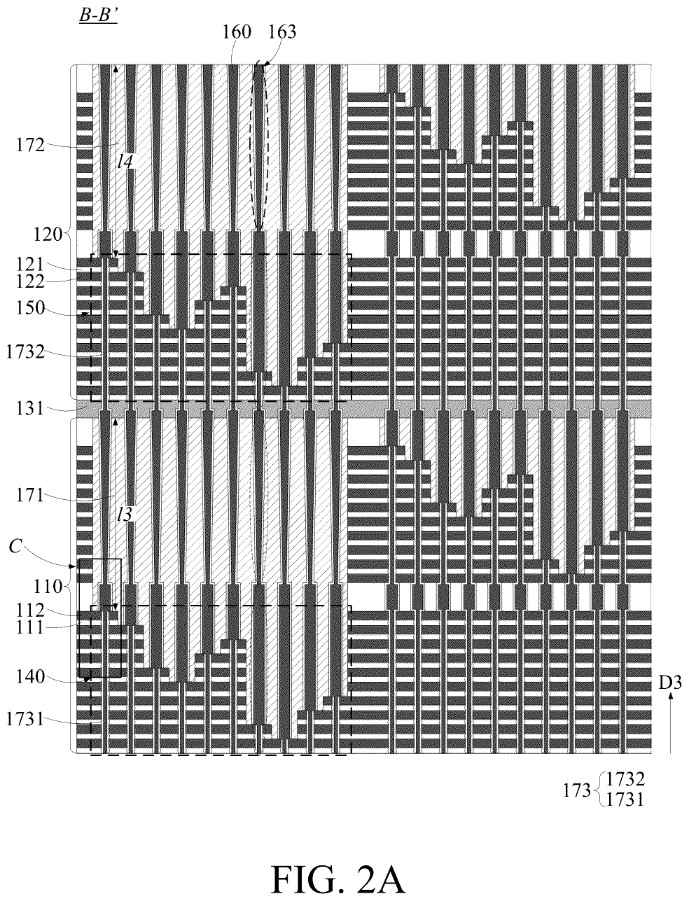

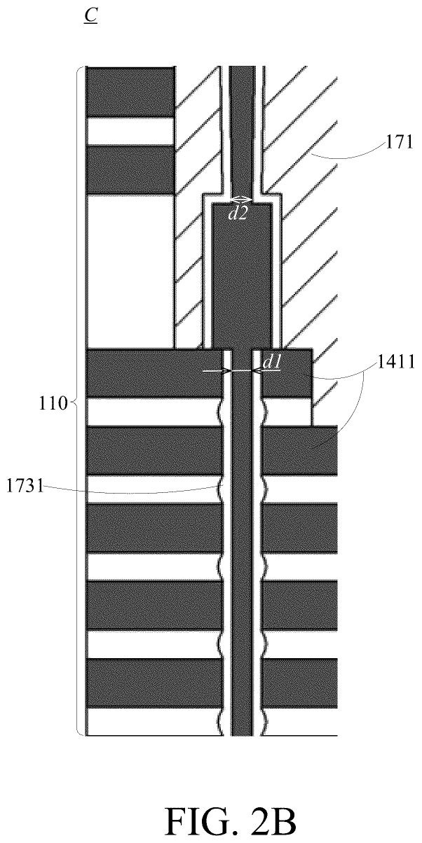

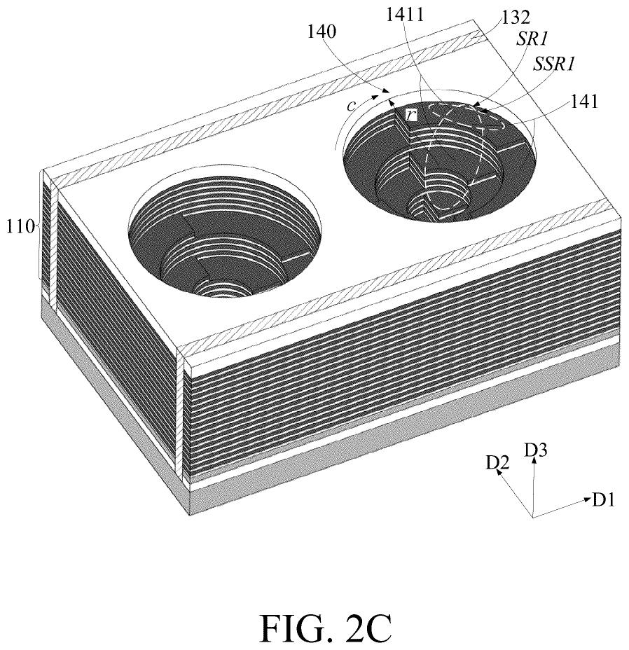

In some implementations, the semiconductor structure 100 may further comprise a first staircase structure, a second staircase structure, and a connection structure. FIG. 2A is a schematic cross-sectional view of a semiconductor structure comprising a first staircase structure, a second staircase structure, and a connection structure provided by an example of the present disclosure. FIG. 2B is a partial enlarged view of region C shown in FIG. 2A. FIG. 2C is a schematic perspective view of a semiconductor structure comprising a first staircase structure provided by an example of the present disclosure. Various components are further described below in conjunction with FIGS. 2A to 2C.

In some implementations, as shown in FIGS. 2A-2C, the first staircase structure 140 may be located in the first stack structure 110. For example, the first staircase structure 140 may be located within the connection region CR shown in FIG. 1C, and may be located between adjacent first gate line isolation structures 132 in the D2 direction. For example, a first stack pair formed by the first dielectric layer 111 and the first gate layer 112 extends by a different size within the connection region CR to form the first staircase structure 140. Thus, the first staircase structure 140 may comprise the first dielectric layer 111 and the first gate layer 112 alternately disposed in the D3 direction.

In some implementations, the first staircase structure 140 may comprise a plurality of first step structures 141 distributed in a circumferential direction c. It should be noted that in the present disclosure, one “step structure” may have two horizontal surfaces and one vertical surface, and the vertical surface may be connected to edges of the two horizontal surfaces. A “staircase structure” may have a combination of a plurality of the above surfaces. Thus, the “step structure” may be part of a “staircase structure”.

In some implementations, a distance between the two horizontal surfaces of the first step structure 141 may be a multiple of a thickness (e.g., a size in the D3 direction) of the first stack pair. In other words, the distance between the two horizontal surfaces of the first step structure 141 is defined by thickness of one or more first stack pairs.

In some implementations, a top layer of the first step structure 141 may be the first gate layer 112. In other words, surfaces of the first gate layer 112 may be two horizontal surfaces of the first step structure 141. It should be noted that the “top layer” in the present disclosure may be a film layer that constitutes a staircase surface.

In some implementations, in a plane perpendicular to the D3 direction, the first staircase structure 140 may comprise a plurality of first step regions SR1 distributed along the circumferential direction c. For example, the plurality of first step regions SR1 may be a plurality of sector regions surrounding a center point. The first step structure 141 may be located within adjacent first step regions SR1. For example, one horizontal surface of the first step structure 141 may be located within the first step region SR1, and another horizontal surface of the first step structure 141 may be located within another first step region SR1 adjacent to the above first step region SR1. From the D3 direction, boundary lines between the vertical surface of the first step structure 141 and two adjacent first step regions SR1 substantially coincide. In the above implementations, the plurality of first step structures 141 distributed along a circumferential direction are disposed in the first staircase structure 140, so that the step area can be effectively reduced, and the issue that the step area is increased due to excessive stacked layers is improved, thereby facilitating reduction of the planar size of the semiconductor structure. In addition, in a case where the two or more memory blocks BLK may share the connection region CR, design margin of size of the first staircase structure 140 in a direction perpendicular to the D3 direction can be increased, thereby increasing the number of the first step structures 141, and further reducing the step area.

In some implementations, the first step structure 141 may comprise a plurality of first sub-step structures 1411 distributed along a radial direction r. Similarly, one “sub-step structure” may also have two horizontal surfaces and one vertical surface, and the vertical surface may be connected to edges of the two horizontal surfaces. A distance between the two horizontal surfaces of the first sub-step structure 1411 may be a multiple of a thickness of the first stack pair. In other words, the distance between the two horizontal surfaces of the first sub-step structure 1411 is defined by thickness of one or more first stack pairs. In this implementation, the plurality of first sub-step structures 1411 distributed along the radial direction r are disposed in the first step structure 141, so that the step area can be further effectively reduced, and the issue that the step area is increased due to excessive stacked layers is further improved, thereby further facilitating reduction of the planar size of the semiconductor structure.

In some implementations, a top layer of the first sub-step structure 1411 may be the first gate layer 112. In other words, surfaces of the first gate layer 112 may be two horizontal surfaces of the first sub-step structure 1411.

In some implementations, in a plane perpendicular to the D3 direction, the first step region SR1 may comprise a plurality of first sub-step regions SSR1 distributed along the radial direction r. For example, in a case where the first step region SR1 is a sector region, the plurality of first sub-step regions SSR1 may be sector regions and sector ring regions coaxially distributed within the sector region. One first sub-step structure 1411 may be located within adjacent first sub-step regions SSR1 in the radial direction r. For example, one horizontal surface of one first sub-step structure 1411 may be located within the first sub-step region SSR1, and another horizontal surface of the first sub-step structure 1411 may be located within another first sub-step region SSR1 adjacent to the first sub-step region SSR1. From the D3 direction, boundary lines between the vertical surface of the first sub-step structure 1411 and two adjacent first sub-step regions SSR1 substantially coincide.

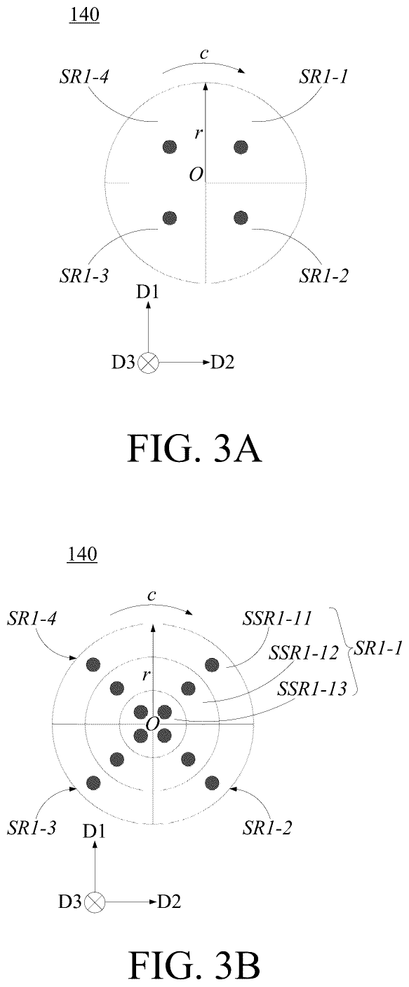

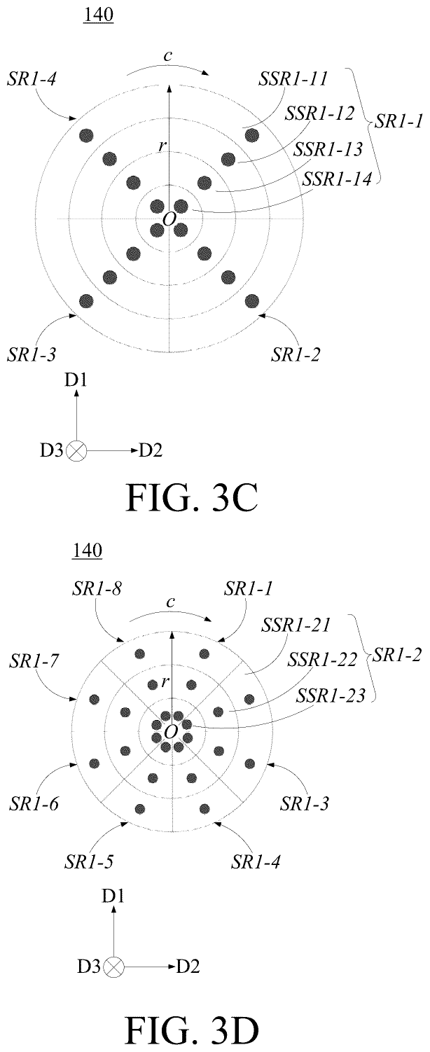

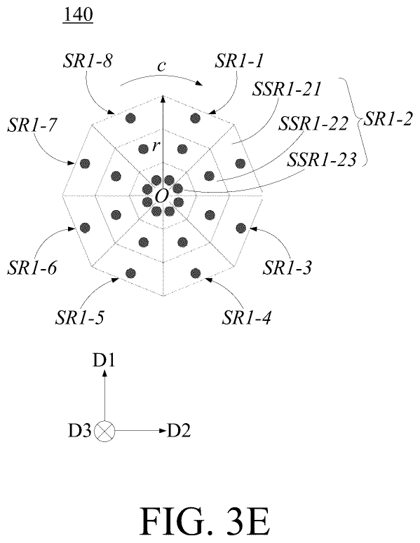

In some examples, the first step region SR1 and the first sub-step region SSR1 may have a variety of shapes and arrangements. FIG. 3A to FIG. 3E are schematic top views of a first staircase structure provided by some examples of the present disclosure. Examples are described below.

As shown in FIG. 3A, in a plane perpendicular to the D3 direction, the first staircase structure 140 may comprise four first step regions SR1-1, SR1-2, SR1-3, and SR 1-4 distributed along the circumferential direction c. The four first step regions SR1-1 to SR1-4 may be four sector regions disposed around the center point O. Each of the first step regions SR1-1 to SR1-4 does not have a first sub-step region.

As shown in FIG. 3B, in a plane perpendicular to the D3 direction, the first staircase structure 140 may comprise four first step regions SR1-1, SR1-2, SR1-3, and SR1-4 distributed along the circumferential direction c. The four first step regions SR1-1 to SR1-4 may be four sector regions disposed around the center point O. For example, the first step region SR1-1 may comprise three first sub-step regions SSR1-11, SSR1-12, SSR1-13 distributed along the radial direction r. The first sub-step regions SSR1-11 and SSR1-12 may be substantially in a sector ring shape, and the first sub-step region SSR1-13 may be substantially in a sector shape. The first sub-step regions SSR1-11 to SSR1-13 are disposed coaxially with respect to the center point O. The other first step regions SR1-2 to SR1-4 have the same sub-region division as the first step region SR1-1.

As shown in FIG. 3C, in a plane perpendicular to the D3 direction, the first staircase structure 140 may comprise four first step regions SR1-1, SR1-2, SR1-3, and SR1-4 distributed along the circumferential direction c. The four first step regions SR1-1 to SR1-4 may be four sector regions disposed around the center point O. For example, the first step region SR1-1 may comprise four first sub-step regions SSR1-11, SSR1-12, SSR1-13, and SSR1-14 distributed along the radial direction r. The first sub-step regions SSR1-11 to SSR1-13 may be substantially in a sector ring shape, and the first sub-step region SSR1-14 may be substantially in a sector shape. The first sub-step regions SSR1-11 to SSR1-14 are disposed coaxially with respect to the center point O. The other first step regions SR1-2-SR1-4 have the same sub-region division as the first step region SR1-1.

As shown in FIG. 3D, in a plane perpendicular to the D3 direction, the first staircase structure 140 may comprise eight first step regions SR1-1, SR1-2, SR1-3, SR1-4, SR1-5, SR1-6, SR1-7, and SR1-8 distributed along the circumferential direction c. The eight first step regions SR1-1 to SR1-8 may be eight sector regions disposed around the center point O. For example, the first step region SR1-2 may comprise three first sub-step regions SSR1-21, SSR1-22, and SSR1-23 distributed along the radial direction r. The first sub-step regions SSR1-21 to SSR1-22 may be substantially in a sector ring shape, and the first sub-step region SSR1-23 may be substantially in a sector shape. The first sub-step regions SSR1-21 to SSR1-23 are disposed coaxially with respect to the center point O. The other first step regions SR1-1 and SR1-3 to SR1-8 have the same sub-region division as the first step region SR1-2.

As shown in FIG. 3E, in a plane perpendicular to the D3 direction, the first staircase structure 140 may comprise eight first step regions SR1-1, SR1-2, SR1-3, SR1-4, SR1-5, SR1-6, SR1-7, and SR1-8 distributed along the circumferential direction c. The eight first step regions SR1-1 to SR1-8 may be eight triangular regions disposed around the center point O. For example, the first step region SR1-2 may comprise three first sub-step regions SSR1-21, SSR 1-22, and SSR 1-23 distributed along the radial direction r. The first sub-step regions SSR1-21 to SSR1-22 may be substantially in a trapezoid shape, and the first sub-step region SSR1-23 may be substantially in a triangle shape. The first sub-step regions SSR1-21 to SSR1-23 are disposed coaxially with respect to the center point O. The other first step regions SR1-1 and SR1-3 to SR1-8 have the same sub-region division as the first step region SR1-2.

It should be noted that, although FIG. 3A to FIG. 3E illustrate the shape of the first staircase structure 140 in the direction perpendicular to the D3 direction and the division of the regions inside the first staircase structure 140, in some other implementations, the shape of the first staircase structure 140 in the direction perpendicular to the D3 direction may further comprise an ellipse, a square, a hexagon, or any other suitable irregular shape, and the shapes of the first step region SR1 and the first sub-step region SSR1 of the first staircase structure 140 in the direction perpendicular to the D3 direction are not specifically limited without departing from the teachings of the present disclosure.

In some implementations, as shown in FIGS. IC and 2A, the second staircase structure 150 may be located in the second stack structure 120. For example, the second staircase structure 150 may be located within the connection region CR and may be located between adjacent first gate line isolation structures 132 in the D2 direction. The second stack pair formed by the second dielectric layer 121 and the second gate layer 122 extends by a different size within the connection region CR to form the second staircase structure 150. Thus, the second staircase structure 150 may comprise the second dielectric layer 121 and the second gate layer 122 alternately disposed in the D3 direction.

In some implementations, a distance between two horizontal surfaces of the second step structure 151 may be a multiple of a thickness (e.g., a size in the D3 direction) of the second stack pair. In other words, the distance between the two horizontal surfaces of the second step structure 151 is defined by thickness of one or more second stack pairs.

In some implementations, a top layer of the second staircase structure 151 may be the second gate layer 122. In other words, surfaces of the second gate layer 122 may be two horizontal surfaces of the second step structure 151.

In some implementations, in a plane perpendicular to the D3 direction, the second staircase structure 150 may comprise a plurality of second step regions SR2 distributed along the circumferential direction c. For example, the plurality of second step regions SR2 may be a plurality of sector regions surrounding the center point. The second step structure 151 may be located within adjacent second step regions SR2. For example, one horizontal surface of the second step structure 151 may be located in the second step region SR2, and another horizontal surface of the second step structure 151 may be located within another second step region SR2 adjacent to the second step region SR2. From the D3 direction, boundary lines between a vertical surface of the second step structure 151 and two adjacent second step regions SR2 substantially coincide. The plurality of second step structures 151 distributed along the circumferential direction c are disposed in the second staircase structure 150, so that the step area can be effectively reduced, the issue that the step area is increased due to excessive stacked layers is improved, thereby facilitating reduction of plane size of the semiconductor structure. In addition, in a case where two or more memory blocks BLK may share the connection region CR, design margin of size of the second staircase structure 150 in the direction perpendicular to the D3 direction can be increased, thereby increasing the number of the second step structures 151, and further reducing the step area.

In some implementations, the second step structure 151 may comprise a plurality of second sub-step structures 1511 distributed along the radial direction r. A distance between two horizontal surfaces of the second sub-step structure 1511 may be a multiple of a thickness of the second stack pair. In other words, the distance between the two horizontal surfaces of the second sub-step structure 1511 is defined by thickness of one or more second stack pairs. In this implementation, the plurality of second sub-step structures 1511 can further effectively reduce the step area, further improve the issue that the step area is increased due to excessive stacked layers, thereby further facilitating reduction of the planar size of the semiconductor structure.

In some implementations, a top layer of the second sub-step structure 1511 may be the second gate layer 122. In other words, surfaces of the second gate layer 122 may be two horizontal surfaces of the second sub-step structure 1511.

In some implementations, in a plane perpendicular to the D3 direction, the second step region SR2 may comprise a plurality of second sub-step regions SSR2 distributed along the radial direction r. For example, in a case where the second step region SR2 is a sector region, the plurality of second sub-step regions SSR2 may be sector regions and sector ring regions coaxially distributed within the sector region. One second sub-step structure 1511 may be located within adjacent second sub-step regions SSR2 in the radial direction r. For example, one horizontal surface of one second sub-step structure 1511 may be located within the second sub-step region SSR2, and another horizontal surface of this second step structure 1511 may be located within another second sub-step region SSR2 adjacent to the above second sub-step region SSR2. From the D3 direction, boundary lines between a vertical surface of this second sub-step structure 1511 and two adjacent second sub-step regions SSR2 substantially coincide.

In some implementations, similar to the first staircase structure 140 shown in FIGS. 3A-3E, in a plane perpendicular to the D3 direction, a shape of the second staircase structure 150 in the direction perpendicular to the D3 direction may comprise a circle, an ellipse, a square, a hexagon, an octagon, or any other suitable irregular shape. In addition, the number and shapes of the second step regions SR2 and the number and shapes of the second sub-step regions SSR2 are not particularly limited without departing from the teachings of the present application.

In some implementations, the first staircase structure 140 and the second staircase structure 150 are at least partially aligned in the D3 direction. For example, from the D3 direction, the first staircase structure 140 and the second staircase structure 150 substantially coincide. For another example, from the D3 direction, the plurality of first step regions SR1 in the first staircase structure 140 and the plurality of second step regions SR2 in the second staircase structure 150 are in one-to-one correspondence and substantially coincide with each other. For yet another example, from the D3 direction, the plurality of first sub-step regions SSR1 in the first staircase structure 140 and the plurality of second sub-step regions SSR2 in the second staircase structure 150 are in one-to-one correspondence and substantially coincide with each other.

It should be noted that staircase surfaces of the first staircase structure 140 may have a changing trend to increase or decrease gradually, or have a changing trend to increase or decrease alternatively. Similarly, staircase surfaces of the second staircase structures 150 may also have a changing trend to increase or decrease gradually, or have a changing trend to increase or decrease alternatively. In addition, the changing trend of the staircase surfaces of the first staircase structure 140 and the second staircase structure 150 may be the same or different.

In some implementations, there are a plurality of first staircase structures 140 and a plurality of second staircase structures 150 (refer to FIG. 1C). From the D3 direction, the first staircase structure 140 and the second staircase structure 150 may be arranged in rows along the D1 direction. For example, the first staircase structure 140 and the second staircase structure 150 may have one or more rows.

In some implementations, the first gate layers 112 that are the top layers of the plurality of first sub-step structures 1411 in each of the first staircase structures 140 are different from each other. The second gate layers 122 that are the top layers of the plurality of second sub-step structures 1511 in each of the second staircase structures 150 are different from each other. Thus, the staircase surfaces of each of the first staircase structures 140 may expose a plurality of different first gate layers 112 in the first stack structure 110, and the staircase surfaces of each of the second staircase structures 150 may expose a plurality of different second gate layers 122 in the second stack structure 120.

In some implementations, as shown in FIGS. 2A-2C, the semiconductor structure 100 may further comprise a first insulation structure 171 and a second insulation structure 172. The first insulation structure 171 may be located on a side of the first staircase structure 140 close to the semiconductor layer 131. The second insulation structure 172 may be located on a side of the second staircase structure 150 away from the semiconductor layer 131. For example, the first insulation structure 171 may have another staircase surface that matches the staircase surface of the first staircase structure 140. A staircase surface of the first insulation structure 171 is away from the semiconductor layer 131. A surface of the first insulation structure 171 away from the semiconductor layer 131 may be substantially planar, and may be substantially level with a surface of the first stack structure 110 towards the semiconductor layer 131. Similarly, the second insulation structure 172 may have yet another staircase surface that matches the staircase surface of the second staircase structure 150. A surface of the second insulation structure 172 away from the semiconductor layer 131 may be substantially planar, and may be substantially level with a surface of the second stack structure 120 away from the semiconductor layer 131.

In some implementations, a material of the first insulation structure 171 may comprise one or more of silicon oxide, silicon nitride, silicon oxynitride, or any other suitable insulation material. A material of the second insulation structure 172 may also comprise one or more of silicon oxide, silicon nitride, silicon oxynitride, or any other suitable insulation material. The materials of the first insulation structure 171 and the second insulation structure 172 may be the same or different. For example, each of the materials of the first insulation structure 171 and the second insulation structure 172 may be silicon oxide. In a case where the portion of the semiconductor layer 131 located within the connection region CR is replaced by the insulation material layer and the material of the insulation material layer and the material of the first insulation structure 171 are the same, there is no obvious interface between the insulation material layer and the first insulation structure 171, and the two may be an integrated structure.

In some implementations, depths of the plurality of first sub-step structures 1411 relative to the semiconductor layer 131 are different from each other. For example, in a case where the staircase surface of the first staircase structure 140 faces the semiconductor layer 131, the “depth” as referred to herein may be a distance (e.g., 13) between the semiconductor layer 131 and one of two horizontal surfaces of one first sub-step structure 1411 closer to the semiconductor layer 131 in the D3 direction. In other words, the first gate layers 112 that are the top layers of the plurality of first sub-step structures 1411 are different from each other.

In some implementations, depths of the plurality of second sub-step structures 1511 relative to the semiconductor layer 131 are different from each other. For example, in a case where the staircase surface of the second staircase structure 150 is away from the semiconductor layer 131, the “depth” as referred to herein may be a distance (e.g., 14) between the semiconductor layer 131 and one of two horizontal surfaces of one second sub-step structure 1511 further away from the semiconductor layer 131 in the D3 direction. In other words, the first gate layers 112 that are the top layers of the plurality of second sub-step structures 1511 are different from each other.

In some implementations, the connection structure 160 may be substantially a columnar structure extending continuously along the D3 direction. For example, the connection structure 160 may extend through the second insulation structure 172, the second staircase structure 150, the semiconductor layer 131 (or the insulation material layer), the first insulation structure 171, and the first staircase structure 140. For example, in a case where the first step region SR1 does not have the first sub-step region SSR1 and the second step region SR2 does not have the second sub-step region SSR2, from the D3 direction, the connection structure 160 may be located within one first step region SR1 and one second step region SR2. Thus, the connection structure 160 may be connected to one first step structure 141 and connected to one second step structure 151. For another example, in a case where the first step region SR1 has the first sub-step region SSR1 and the second step region SR2 has the second sub-step region SSR2, from the D3 direction, the connection structure 160 may be located within one first sub-step region SSR1 and one second sub-step region SSR2. Thus, the connection structure 160 may be connected to one first sub-step structure 1411 and connected to one second sub-step structure 1511.

In some implementations, a material of the connection structure 160 may comprise one or more of titanium, titanium nitride, tantalum, tantalum nitride, polysilicon, amorphous silicon, tungsten, molybdenum, copper, aluminum, ruthenium, metal silicide, or any other suitable conductive material.

In some implementations, the semiconductor structure 100 may further comprise an isolation layer 173. The isolation layer 173 may surround portions of the connection structure 160 extending through the first staircase structure 140 and the second staircase structure 150. For example, the isolation layer 173 may comprise a first isolation portion 1731 and a second isolation portion 1732. The first isolation portion 1731 and the second isolation portion 1732 may be substantially in a tube shape. The first isolation portion 1731 may be sleeved on a portion of the connection structure 160 extending through the first staircase structure 140. For example, inner side of the first isolation portion 1731 may be in contact with the connection structure 160, and outer side of the first isolation portion 1731 may be in contact with the first staircase structure 140. The second isolation portion 1732 may be sleeved on a portion of the connection structure 160 extending through the second staircase structure 150. For example, inner side of the second isolation portion 1732 may be in contact with the connection structure 160, and outer side of the second isolation portion 1732 may be in contact with the second staircase structure 150. A material of the isolation layer 173 may comprise one or more of silicon oxide, silicon nitride, silicon oxynitride, or any other suitable insulation material.

In some implementations, the isolation layer 173 may also surround portions of the connection structure 160 extending through the first insulation structure 171 and the second insulation structure 172. In a case where the material of the isolation layer 173 is the same as the material of the first insulation structure 171, there is no obvious interface between the two, and the two may be an integrated structure. Similarly, in a case where the material of the isolation layer 173 is the same as the material of the second isolation structure 172, there is no obvious interface between the two, and the two may be an integrated structure.

In some implementations, in a plane perpendicular to the D3 direction, a size d2 of a portion of the connection structure 160 extending through the first insulation structure 171 is greater than a size dl of a portion of the connection structure 160 extending through the first staircase structure 140. For example, the size dl may be a maximum size of the portion of the connection structure 160 extending through the first staircase structure 140 in a plane perpendicular to the D3 direction. The size d2 may be a minimum size of the portion of the connection structure 160 extending through the first insulation structure 171 in a plane perpendicular to the D3 direction. Thus, the portion of the connection structure 160 extending through the first insulation structure 171 with a larger size in a plane perpendicular to the D3 direction may be connected to one first gate layer 112 in the first sub-step structure 1411, for example, in contact with the first gate layer 112 that is the top layer.

In some implementations, in a plane perpendicular to the D3 direction, a (e.g., minimum) size of a portion of the connection structure 160 extending through the second insulation structure 172 is greater than a (e.g., maximum) size of a portion of the connection structure 160 extending through the second staircase structure 150. Thus, the portion of the connection structure 160 extending through the second insulation structure 172 with a larger size in a plane perpendicular to the D3 direction may be connected to one second gate layer 122 in the second sub-step structure 1511, for example, in contact with the second gate layer 122 that is the top layer.

In the above implementations, one connection structure 160 can lead out one first gate layer 112 and one second gate layer 122, which can be connected to each other by the connection structure 160. The isolation layer 173 can electrically isolate the connection structure 160 from other first gate layers 112 that are not the top layers in the first sub-staircase structure 1411 and other second gate layers 122 that are not the top layers in the second sub-staircase structure 1511. By connecting the connection structure 160 to one first step structure 141 in the first staircase structure 140 and one second step structure 151 in the second staircase structure 150 that are stack disposed, the step area can be further reduced, and the control difficulty of the semiconductor structure can be reduced.

In some implementations, the connection structure 160 may comprise a plurality of sub-connection structures 163 distributed along the D3 direction. In a plane perpendicular to the D3 direction, a size (e.g., diameter) of the sub-connection structure 163 may be substantially incremented along the D3 direction. In this implementation, a plurality of sub-connection structures 163 are disposed to facilitate reduction of the manufacturing difficulty of the connection structure 160 and improve the yield of the connection structure 160.

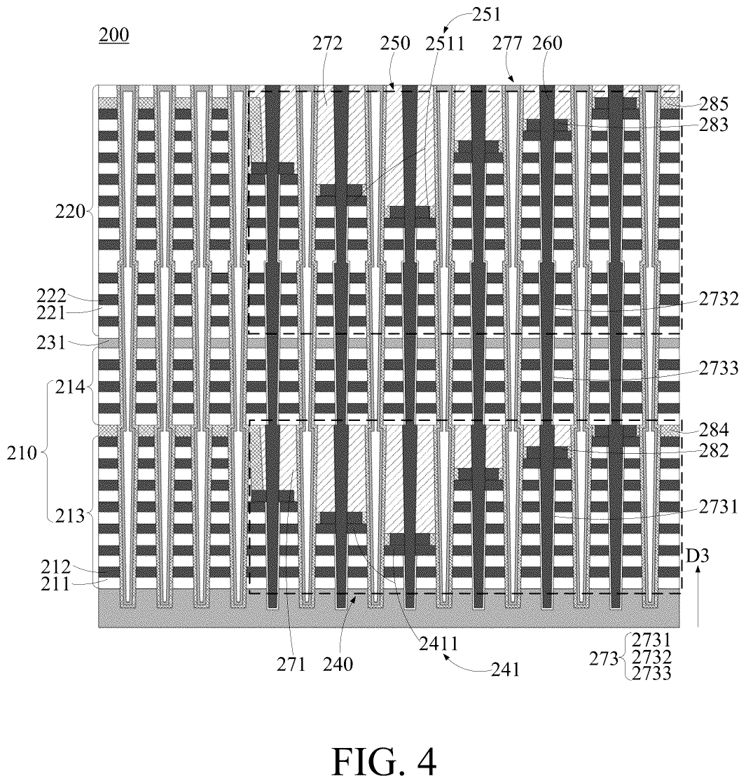

FIG. 4 is a schematic cross-sectional view of a semiconductor structure comprising a first staircase structure, a second staircase structure, and a connection structure provided by another example of the present disclosure. For the purpose of brevity, in this example and the following examples, the same content as the previous example are not described herein again.

In some implementations, as shown in FIG. 4, the semiconductor structure 200 may comprise a first stack structure 210, a second stack structure 220, a semiconductor layer 231, a first staircase structure 240, a second staircase structure 250, and a connection structure 260. The second stack structure 220 may be located on a side of the first stack structure 210. The semiconductor layer 231 is located between the first stack structure 210 and the second stack structure 220. The first staircase structure 240 may be located in the first stack structure 210 and may comprise a plurality of first step structures 241 distributed along a circumferential direction. The second staircase structure 250 may be located in the second stack structure 220 and may comprise a plurality of second step structures 251 distributed along a circumferential direction. The connection structure 260 may extend along the D3 direction and may be connected to one first step structure 241 and one second step structure 251.

In some implementations, the first stack structure 210 may comprise a first dielectric layer 211 and a first gate layer 212 alternately disposed in the D3 direction. For example, the first stack structure 210 may comprise a first stack portion 213 and a second stack portion 214 distributed along the D3 direction. The first stack portion 213 and the second stack portion 214 may each comprise a first dielectric layer 211 and a first gate layer 212 that are alternately disposed. The first staircase structure 240 may be located in the first stack portion 213. Similarly, the second stack structure 220 may comprise a second dielectric layer 221 and a second gate layer 222 alternately disposed in the D3 direction.

In some implementations, the first step structure 241 may comprise a plurality of first sub-step structures 2411 distributed along a radial direction. The second step structure 251 may comprise a plurality of second sub-step structures 2511 distributed along a radial direction.

In some implementations, the semiconductor structure 200 may further comprise a first insulation structure 271 and a second insulation structure 272. The first insulation structure 271 may be located on a side of the first staircase structure 240 close to the semiconductor layer 231. The second insulation structure 272 may be located on a side of the second staircase structure 250 away from the semiconductor layer 231. In a case where the first stack structure 210 comprises the first stack portion 213 and the second stack portion 214 and the first staircase structure 240 is located in the first stack portion 213, the second stack portion 214 may cover the first insulation structure 271. In other words, the first insulation structure 271 may be filled in at least a portion of cavity between the second stack portion 214 and the first staircase structure 240.

In some implementations, the connection structure 260 may be substantially a columnar structure extending continuously along the D3 direction. For example, the connection structure 260 may extend through the second insulation structure 272, the second staircase structure 250, the semiconductor layer 231 (or the insulation material layer), the first insulation structure 271, and the first staircase structure 240. In a case where the first stack structure 210 comprises the first stack portion 213 and the second stack portion 214 and the first staircase structure 240 is located in the first stack portion 213, the connection structure 260 may sequentially extend through the second insulation structure 272, the second staircase structure 250, the semiconductor layer 231 (or the insulation material layer), the second stack portion 214, the first insulation structure 271, and the first staircase structure 240.

In some implementations, the semiconductor structure 200 may further comprise a first surrounding portion 282. The first surrounding portion 282 may surround the connection structure 260 and may be in contact with the first staircase structure 240. For example, the first surrounding portion 282 may be sleeved on the connection structure 260 and may be in contact with the connection structure 260. In a plane perpendicular to the D3 direction, an outer diameter of the first surrounding portion 282 may be greater than a size of a portion of the connection structure 260 extending through the first staircase structure 240, and greater than a size of a portion of the connection structure 260 extending through the first insulation structure 271. A size of the first surrounding portion 282 in the D3 direction may be substantially the same as a size of one first dielectric layer 211 in the D3 direction. The first surrounding portion 282 may be in contact with the first gate layer 212 that is the top layer of one first step structure 241 (or one first sub-step structure 2411). In addition, from the D3 direction, the first surrounding portion 282 may be located within an area defined by one horizontal surface of one first step structure 241 (or one first sub-step structure 2411).

In some implementations, a material of the first surrounding portion 282 may comprise one or more of titanium, titanium nitride, tantalum, tantalum nitride, polysilicon, amorphous silicon, tungsten, molybdenum, copper, aluminum, ruthenium, metal silicide, or any other suitable conductive material. For example, the material of the first surrounding portion 282 may be the same as the material of the connection structure 260, and in this case, there is no obvious interface between the two, and the two may be an integrated structure.

In some implementations, the semiconductor structure 200 may further comprise a second surrounding portion 283. The second surrounding portion 283 may surround the connection structure 260 and may be in contact with the second staircase structure 250. For example, the second surrounding portion 283 may be sleeved on the connection structure 260 and may be in contact with the connection structure 260. In a plane perpendicular to the D3 direction, an outer diameter of the second surrounding portion 283 may be greater than a size of a portion of the connection structure 260 extending through the second staircase structure 250, and may be greater than a size of a portion of the connection structure 260 extending through the second insulation structure 272. A size of the first surrounding portion 282 in the D3 direction may be substantially the same as a size of one second dielectric layer 221 in the D3 direction. The second surrounding portion 283 may be in contact with the second gate layer 222 that is the top layer of one second step structure 251 (or one second sub-step structure 2511). In addition, from the D3 direction, the second surrounding portion 283 may be located within an arca defined by one horizontal surface of one second step structure 251 (or one second sub-step structure 2511).

In some implementations, a material of the second surrounding portion 283 may comprise one or more of titanium, titanium nitride, tantalum, tantalum nitride, polysilicon, amorphous silicon, tungsten, molybdenum, copper, aluminum, ruthenium, metal silicide, or any other suitable conductive material. For example, the material of the second surrounding portion 283 may be the same as the material of the connection structure 260, and in this case, there is no obvious interface between the two, and the two may be an integrated structure. The materials of the first surround portion 282 and the second surround portion 283 may be the same or different.

In some implementations, the semiconductor structure 200 may further comprise an isolation layer 273. The isolation layer 273 may surround portions of the connection structure 260 extending through the first staircase structure 240 and the second staircase structure 250. For example, the isolation layer 273 may comprise a first isolation portion 2731 and a second isolation portion 2732. The first isolation portion 2731 may be sleeved on a portion of the connection structure 260 extending through the first staircase structure 240. The second isolation portion 2732 may be sleeved on a portion of the connection structure 260 extending through the second staircase structure 250. In a case where the first stack structure 210 comprises the first stack portion 213 and the second stack portion 214 and the first staircase structure 240 is located in the first stack portion 213, the isolation layer 273 may further comprise a third isolation portion 2733. The third isolation portion 2733 may surround a portion of the connection structure 260 extending through the second stack portion 214.

As described above, one connection structure 260 can lead out one first gate layer 212 and one second gate layer 222, which can be connected to each other by the connection structure 260. The isolation layer 273 can electrically isolate the connection structure 260 from other first gate layers 212 that are not the top layers in the first step structure 241 (or the first sub-step structure 2411), and other second gate layers 222 that are not the top layers in the second step structure 251 (or the second sub-step structure 2511). Optionally, the isolation layer 273 can further electrically isolate the connection structure 260 from the first gate layers 212 in the second stack portion 214.

In some implementations, the semiconductor structure 200 further comprises a first insulation layer 284. The first insulation layer 284 may be located between the first staircase structure 240 and the first insulation structure 271. For example, the first insulation layer 284 may cover a staircase surface of the first staircase structure 240. A thickness (e.g., a size in a direction perpendicular to the staircase surface) of the first insulation layer 284 may be substantially the same as the size of the first surrounding portion 282 in the D3 direction. The first surrounding portion 282 may be embedded in the first insulation layer 284. A material of the first insulation layer 284 may comprise one or more of silicon oxide, silicon nitride, silicon oxynitride, or any other suitable insulation material. For example, the material of the first insulation layer 284 may be different from the material of the first dielectric layer 211. In a case where the material of the first dielectric layer 211 is silicon oxide, the material of the first insulation layer 284 may comprise silicon nitride, such as carbon-doped silicon nitride.

In some implementations, the semiconductor structure 200 may further comprise a second insulation layer 285. The second insulation layer 285 may be located between the second staircase structure 250 and the second insulation structure 272. For example, the second insulation layer 285 may cover a staircase surface of the second staircase structure 250. A thickness (e.g., a size in a direction perpendicular to the staircase surface) of the second insulation layer 285 may be substantially the same as a size of the second surrounding portion 283 in the D3 direction. The second surrounding portion 283 may be embedded in the second insulation layer 285. A material of the second insulation layer 285 may comprise one or more of silicon oxide, silicon nitride, silicon oxynitride, or any other suitable insulation material. For example, the material of the second insulation layer 285 may be different from the material of the second dielectric layer 221. In a case where the material of the second dielectric layer 221 is silicon oxide, the material of the second insulation layer 285 may be silicon nitride, such as carbon-doped silicon nitride.

In some implementations, the semiconductor structure 200 may further comprise a second channel structure 277. The second channel structure 277 may extend through the second staircase structure 250 and the first staircase structure 240. For example, the second channel structure 277 may be substantially in a column shape, and its internal structure is the same as that of the first channel structure 176 shown in FIG. 1D, and details are not described herein again. In addition, the second channel structure 277 may be located within the connection region CR and not connected to the first bit line portion and the second bit line portion. The second channel structure 277 may be configured to provide mechanical support and/or load balancing.

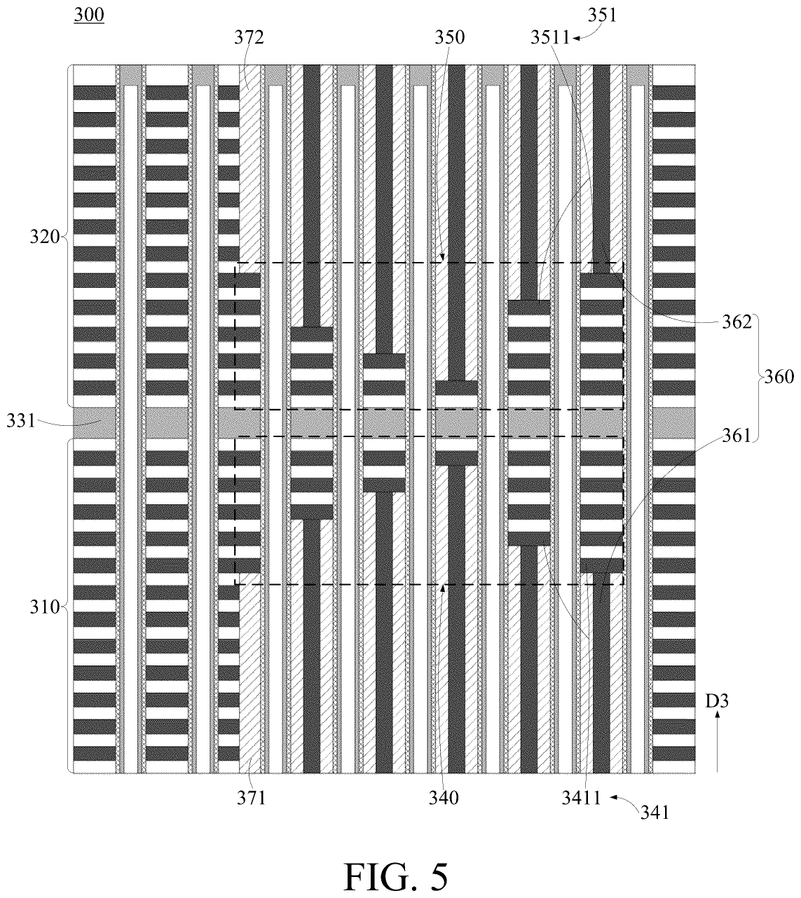

FIG. 5 is a schematic cross-sectional view of a semiconductor structure comprising a first staircase structure, a second staircase structure, and a connection structure provided by yet another example of the present disclosure.

In some implementations, as shown in FIG. 5, the semiconductor structure 300 may comprise a first stack structure 310, a second stack structure 320, a semiconductor layer 331, a first staircase structure 340, a second staircase structure 350, and a connection structure 360. The second stack structure 320 may be located on a side of the first stack structure 310. The semiconductor layer 331 is located between the first stack structure 310 and the second stack structure 320. The first staircase structure 340 may be located in the first stack structure 310 and may comprise a plurality of first step structures 341 distributed along a circumferential direction. The second staircase structure 350 may be located in the second stack structure 320 and may comprise a plurality of second step structures 351 distributed along a circumferential direction. The connection structure 360 may extend along the D3 direction and be connected to one first step structure 341 and one second step structure 351.

In some implementations, the first stack structure 310 may comprise a first dielectric layer 311 and a first gate layer 312 alternately disposed in the D3 direction. Similarly, the second stack structure 320 may comprise a second dielectric layer 321 and a second gate layer 322 alternately disposed in the D3 direction.

In some implementations, the first step structure 341 may comprise a plurality of first sub-step structures 3411 distributed along a radial direction. The second step structure 351 may comprise a plurality of second sub-step structures 3511 distributed along a radial direction. For example, the first insulation structure 371 may have another staircase surface that matches a staircase surface of the first staircase structure 340. A staircase surface of the first insulation structure 371 faces the semiconductor layer 331. A surface of the first insulation structure 371 away from the semiconductor layer 331 may be substantially planar, and may be substantially level with a surface of the first stack structure 310 away from the semiconductor layer 331. Similarly, the second insulation structure 372 may have yet another staircase surface that matches a staircase surface of the second staircase structure 350. A staircase surface of the second insulation structure 372 faces the semiconductor layer 331. A surface of the second insulation structure 372 away from the semiconductor layer 331 may be substantially planar, and may be substantially level with a surface of the second stack structure 320 away from the semiconductor layer 331.

In some implementations, the connection structure 360 may comprise a first connection portion 361 and a second connection portion 362. The first connection portion 361 may extend through the first insulation structure 371 and extend to the first staircase structure 340. The second connection portion 362 may extend through the second insulation structure 372 and extend to the second staircase structure 350. For example, the first connection portion 361 and the second connection portion 362 may be structures separate from each other. The first connection portion 361 may be substantially a columnar structure extending continuously along the D3 direction, and the second connection portion 362 may also be substantially a columnar structure extending continuously along the D3 direction. In the D3 direction, the first connection portion 361 and the second connection portion 362 may be substantially aligned. In other words, from the D3 direction, the first connection portion 361 and the second connection portion 362 may substantially coincide. Further, the first connection portion 361 may be located within an area defined by one horizontal surface of the first step structure 341 (or the first sub-step structure 3411). The second connection portion 362 may be located within an area defined by one horizontal surface of the second step structure 351 (or the second sub-step structure 3511). Thus, the first connection portion 361 may be connected to one first step structure 341 (or the first sub-step structure 3411), and the second connection portion 362 may be connected to one second step structure 351 (or the second sub-step structure 3511).

In the above implementations, the first connection portion 361 can lead out the first gate layer 312 that is the top layer in one first step structure 341 (or the first sub-step structure 3411), and the second connection portion 362 can lead out the second gate layer 322 that is the top layer in one second step structure 351 (or the second sub-step structure 3511). For example, the first connection portion 361 and the second connection portion 362 may be connected to each other, for example, by an interconnect line and/or an interconnect channel. For another example, the first connection portion 361 and the second connection portion 362 may not be connected to each other, so that each first gate layer 312 and each second gate layer 322 can be individually controlled.

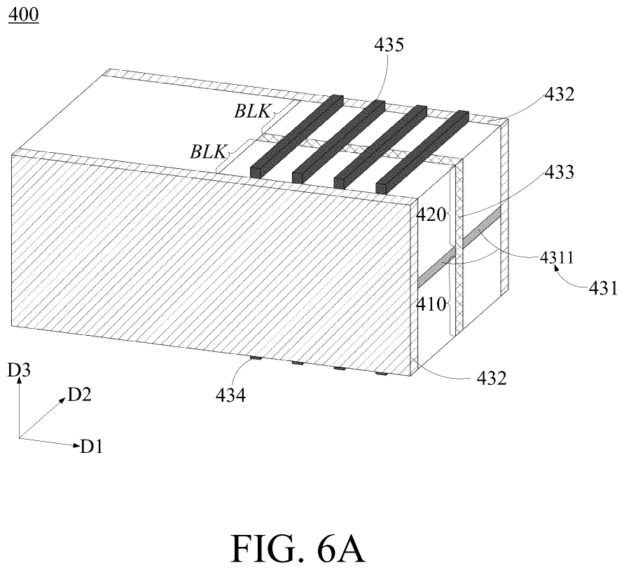

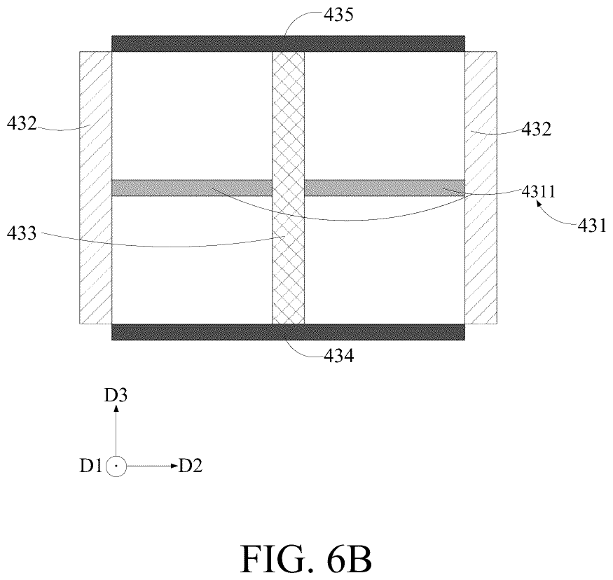

FIG. 6A is a schematic perspective view of a semiconductor structure provided by another example of the present disclosure. FIG. 6B is a schematic cross-sectional view of a semiconductor structure provided by another example of the present disclosure.

As shown in FIG. 6A to FIG. 6B, the semiconductor structure 400 may comprise a first stack structure 410, a second stack structure 420, a semiconductor layer 431, a first gate line isolation structure 432, and a second gate line isolation structure 433. The second stack structure 420 may be located on a side of the first stack structure 410. The semiconductor layer 431 may be located between the first stack structure 410 and the second stack structure 420. The first gate line isolation structure 432 may extend through the second stack structure 420, the semiconductor layer 431, and the first stack structure 410 along the D3 direction, and extend along the D1 direction. The second gate line isolation structure 433 may extend through the second stack structure 420 and the first stack structure 410 along the D3 direction, and may extend along the D1 direction. The second gate line isolation structures 433 may be located between adjacent first gate line isolation structures 432 in the D2 direction.

In some implementations, the second gate line isolation structure 433 may extend continuously along the D1 direction within the memory region AR, and sequentially extend through the second stack structure 420, the semiconductor layer 431 and the first stack structure 410 along the D3 direction. For example, the semiconductor layer 431 may be divided into semiconductor portions 4311 by the second gate line isolation structure 433. The semiconductor portion 4311 may extend (e.g., continuously) between adjacent first gate line isolation structure 432 and second gate line isolation structure 433 in the D2 direction, or extend (e.g., continuously) between adjacent second gate line isolation structures 433 in the D2 direction. Two semiconductor portions 4311 located on two opposite sides of the second gate line isolation structure 433 in the D2 direction are electrically isolated.

In some implementations, the semiconductor structure 400 may further comprise a first bit line structure 434 and a second bit line structure 435. The first bit line structure 434 may be located on a side of the first stack structure 410 away from the semiconductor layer 431. The first bit line structure 434 may extend continuously along the D2 direction and may be located within the memory region AR. The second bit line structure 435 may be located on a side of the second stack structure 420 away from the semiconductor layer 431. The second bit line structure 435 may extend continuously along the D2 direction and may be located in the memory region AR. In the above implementations, two or more memory blocks BLK may share a first bit line structure 434 and a second bit line structure 435, and a single semiconductor portion 4311 may individually control one memory block BLK. The two or more memory blocks BLK may share the connection region CR to reduce the planar size of the connection region CR.

In some other implementations, as described above, the first bit line structure 434 may comprise a plurality of first bit line portions distributed in the D2 direction, the first bit line portion may be located between the first gate line isolation structure 432 and the second gate line isolation structure 433, or between adjacent second gate line isolation structures 433. The second bit line structure 435 may comprise a plurality of second bit line portions distributed in the D2 direction, the second bit line portion may be located between the first gate line isolation structure 432 and the second gate line isolation structure 433, or between adjacent second gate line isolation structures 433. In this implementation, the first bit line portion and the second bit line portion may individually control one memory block BLK, and the single semiconductor portion 4311 may individually control one memory block BLK, which facilitates improving control reliability.

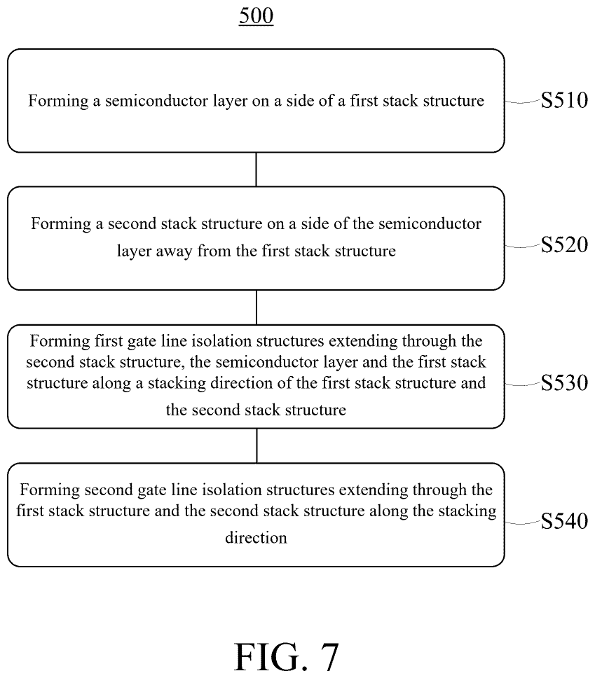

Some examples of the present disclosure further provide a manufacturing method of a semiconductor structure. FIG. 7 is a schematic flowchart of a manufacturing method of a semiconductor structure provide by an example of the present disclosure. As shown in FIG. 7, a manufacturing method 500 of a semiconductor structure (hereinafter referred to as the manufacturing method 500) may comprise the following operations.
S510: forming a semiconductor layer on a side of a first stack structure.
S520: forming a second stack structure on a side of the semiconductor layer away from the first stack structure.
S530: forming a first gate line isolation structure extending through the second stack structure, the semiconductor layer, and the first stack structure along a stacking direction of the first stack structure and the second stack structure.
S540: forming a second gate line isolation structure extending through the first stack structure and the second stack structure along the stacking direction.

The first gate line isolation structure and the second gate line isolation structure extend along a first direction, and the second gate line isolation structure is located between adjacent first gate line isolation structures in a second direction intersecting with the first direction.

According to the manufacturing method provided by the example of the present disclosure, the semiconductor layer is formed between the first stack structure and the second stack structure, which can break the limitation on the number of stacked layers and help to improve the unit memory density. The first gate line isolation structure and the second gate line isolation structure may each be configured to divide the first stack structure and the second stack structure into memory blocks, which facilitates reduction of the control difficulty of the semiconductor structure and reduction of the planar size of the semiconductor structure.

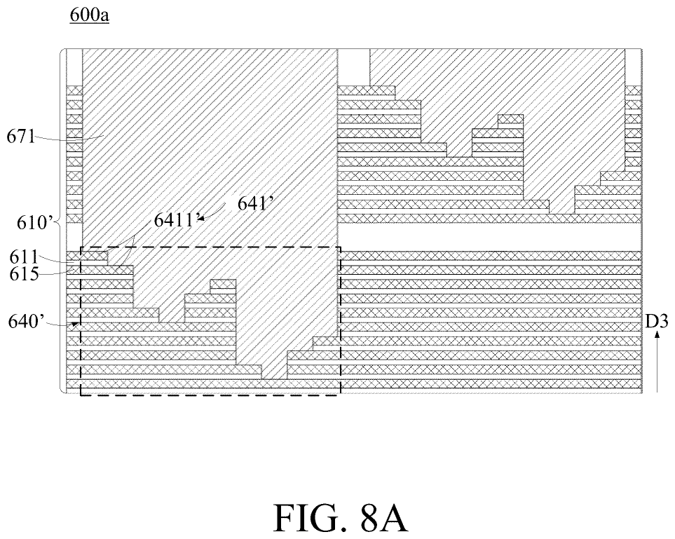

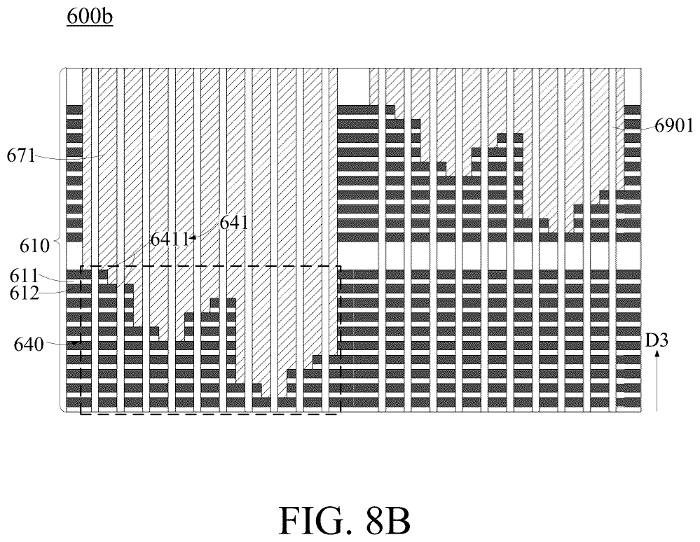

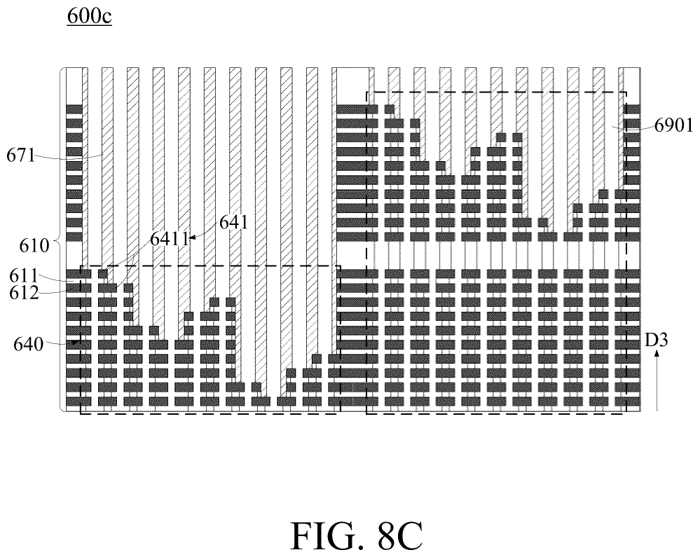

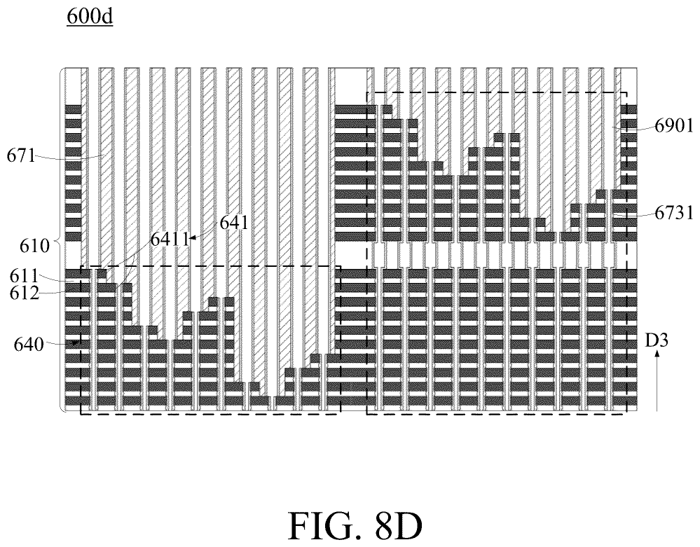

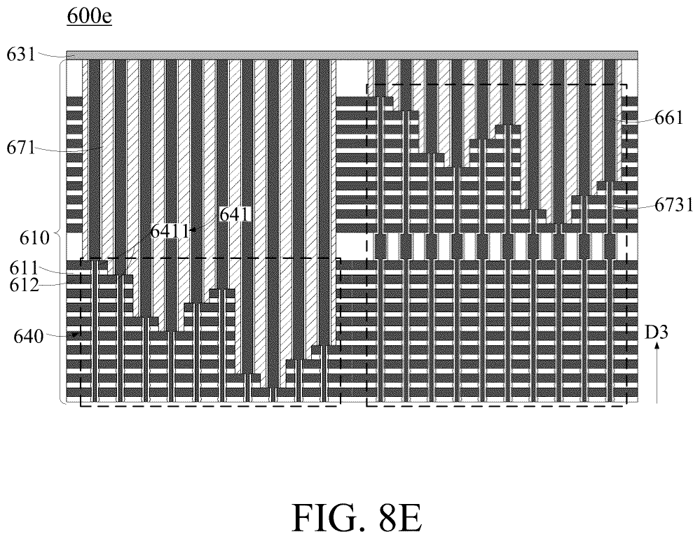

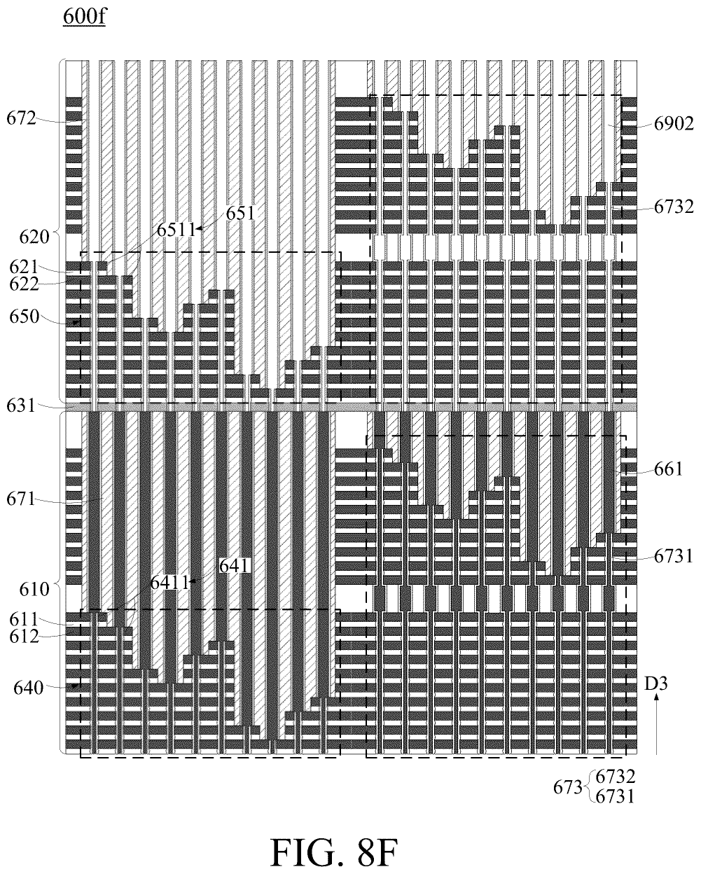

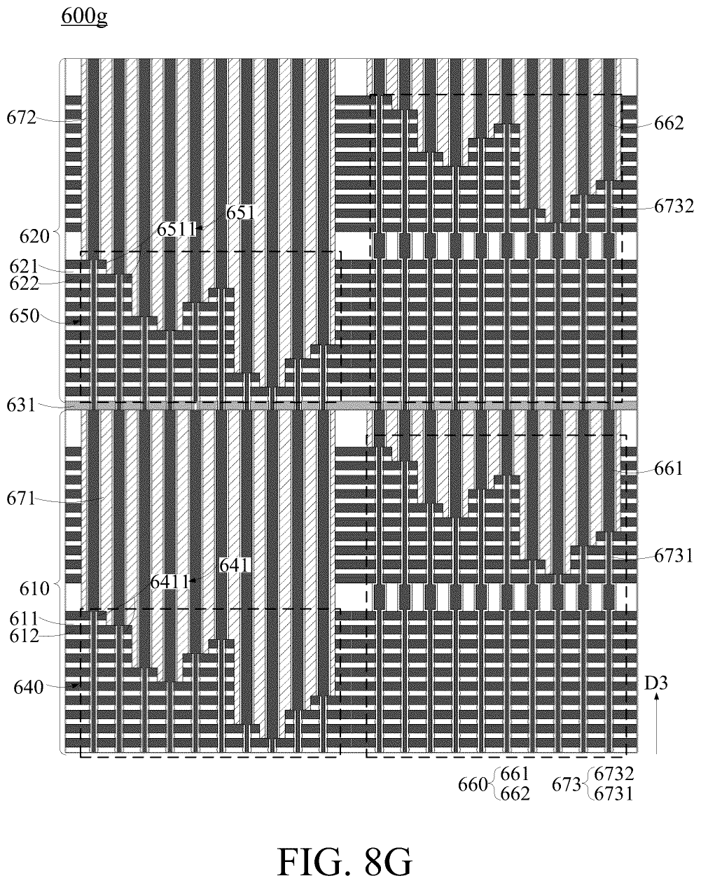

FIG. 8A to FIG. 8G are schematic cross-sectional views of a semiconductor structure in a manufacturing process provided by an example of the present disclosure. FIG. 8A illustrates an intermediate structure 600a after forming an initial first stack structure 610′ and an initial first staircase structure 640′. FIG. 8B illustrates an intermediate structure 600b after forming a first stack structure 610, a first staircase structure 640, and a first connection hole 6901. FIG. 8C illustrates an intermediate structure 600c after enlarging a portion of the first connection hole 6901. FIG. 8D illustrates an intermediate structure 600d after forming a first isolation portion 6731. FIG. 8E illustrates an intermediate structure 600e after the forming a first connection portion 661 and a semiconductor layer 631. FIG. 8F illustrates an intermediate structure 600f after forming a second stack structure 620, a second staircase structure 650, a second connection hole 6902, and a second isolation portion 6732. FIG. 8G illustrates an intermediate structure 600g after forming a second connection portion 662.

The manufacturing method 500 comprising the operations S510 to S540 is exemplarily described below in conjunction with FIGS. 8A to 8G.

In some implementations, as shown in FIG. 8A, the initial first stack structure 610′ may comprise a first dielectric layer 611 and a first sacrificial layer 615 that are alternately formed in a D3 direction. For example, the first dielectric layer 611 and the first sacrificial layer 615 in the initial first stack structure 610′ may be located within the memory region AR and the connection region CR shown in FIG. IC. Materials of the first sacrificial layer 615 and the first dielectric layer 611 may be different. In a case where the material of the first dielectric layer 611 is silicon oxide, the material of the first sacrificial layer 615 may comprise silicon nitride. For example, the first dielectric layer 611 and the first sacrificial layer 615 may be formed by using a thin film deposition process such as chemical vapor deposition (CVD), physical vapor deposition (PVD), atomic layer deposition (ALD), or any combination thereof.

In some implementations, the initial first staircase structure 640′ may be formed in the initial first stack structure 610′. The initial first staircase structure 640′ may comprise a plurality of initial first step structures 641′ distributed along a circumferential direction. Optionally, the initial first step structure 641′ may comprise a plurality of initial first sub-step structures 6411′ distributed along a radial direction. The initial first staircase structure 640′ may be formed by trim-etching the initial first stack structure 610′. Thus, the initial first staircase structure 640′ may comprise the first dielectric layer 611 and the first sacrificial layer 615 alternately disposed in the D3 direction. A top layer of each initial first step structure 641′ (or each initial first sub-step structure 6411′) is a first sacrificial layer 615. For example, a plurality of initial first staircase structures 640′ may be located within the connection region CR shown in FIG. IC.

In some implementations, as shown in FIG. 8B, the first sacrificial layer 615 may be replaced with a first gate layer 612, so that the initial first stack structure 610′ is converted into the first stack structure 610. For example, a first gate line slit and a second gate line slit extending through the initial first stack structure 610′ may be first formed, and the first sacrificial layer 615 may be replaced with the first gate layer 612 by using the first gate line slit and/or the second gate line slit. The first gate line slit may correspond to an outer contour of a portion of the first stack structure 110 through which the first gate line isolation structure 132 extends shown in FIG. 1A. The second gate line slit may correspond to an outer contour of the second gate line isolation portion 1331-1 located in the first stack structure 110 shown in FIG. 1A. For example, the first gate line slit and the second gate line slit may extend along a D1 direction by means of patterning design, and the second gate line slit is located between adjacent first gate line slits in the D2 direction. Thus, the initial first staircase structure 640′ is converted into the first staircase structure 640. The first staircase structure 640 may comprise the first dielectric layer 611 and the first gate layer 612 alternately disposed in the D3 direction. A top layer of each first step structure 641 (or each first sub-step structure 5411) is the first gate layer 612.

In some implementations, after forming the first stack structure 610, one or more insulation materials may be filled in the first gate line slit and the second gate line slit, or a first oxide layer is first formed by deposition and then a first polysilicon body is formed by deposition, so that a portion of the first gate line isolation structure and the second gate line isolation portion are respectively formed.

In some implementations, as shown in FIGS. 8A and 8B, a first insulation structure 671 may be formed on a side of the first staircase structure 640 having a staircase surface by using a thin film deposition process such as CVD, PVD, ALD, or any combination thereof. In other words, the first insulation structure 671 may be formed on a side of the first staircase structure 640 close to the semiconductor layer 631 (referring to FIG. 8E) to be formed.

In some implementations, as shown in FIG. 8B, the first connection hole 6901 extending through the first insulation structure 671 and the first staircase structure 640 is formed by using an etching (e.g., dry etching and/or wet etching) process. For example, the first connection hole 6901 may extend along the D3 direction. From the D3 direction, the first connection hole 6901 may be located within an area defined by one horizontal surface of one first step structure 641 (or the first sub-step structure 6411).

In some implementations, as shown in FIGS. 8B and 8C, portions of the first insulation structure 671 and the first dielectric layer 611 at the periphery of the first connection hole 6901 may be removed by using an etching (e.g., wet etching) process. In other words, portions of the first connection hole 6901 extending through the first insulation structure 671 and the first dielectric layer 611 may be enlarged. After the above process, in a plane perpendicular to the D3 direction, each of a size (e.g., a diameter) of a portion of the first connection hole 6901 extending through the first insulation structure 671 and a size (e.g., a diameter) of a portion of the first connection hole 6901 extending through the first dielectric layer 611 is greater than a size (e.g., a diameter) of a portion of the first connection hole 6901 extending through the first gate layer 612.

In some implementations, as shown in FIGS. 8C and 8D, the manufacturing method 500 may further comprise an operation of forming a first isolation portion 6731 on a sidewall of a portion of the first staircase structure 640 through which the first connection hole 6901 extends. In an example, an initial first isolation portion (not shown) may be formed on a sidewall of the first connection hole 6901 by using a thin film deposition process such as CVD, PVD, ALD, or any combination thereof. For example, the initial first isolation portion may cover a surface of the first gate layer 612 that is the top layer in the first staircase structure 640.

Further, a portion of the initial first isolation portion located on the surface of the first gate layer 612 that is the top layer in the first staircase structure 640 may be removed by using an etching (e.g., dry etching) process. Thus, the first gate layer 612 that is the top layer in the first staircase structure 640 is exposed. Since the size of the portion of the first connection hole 6901 extending through the first insulation portion 671 is greater than a size of a portion of the first connection hole 6901 extending through the first gate layer 612 in the first staircase structure 640 in a plane perpendicular to the D3 direction, in the above etching process, a portion of the initial first isolation portion located on a sidewall of a portion of the first connection hole 6901 extending through the first staircase structure 640 is kept, that is, the remaining unetched initial first isolation portion may be the first isolation portion 6731.

Further, as shown in FIGS. 8D and 8E, a conductive material may be filled in the first connection hole 6901 with the first isolation portion 6731 formed by using a thin film deposition process such as CVD, PVD, ALD, or any combination thereof, to form the first connection portion 661. The first connection portion 661 may be connected to (e.g., in contact with) the first gate layer 612 that is the top layer in the first staircase structure 640, and electrically isolated from the first gate layer 612 that is not the top layer in the first staircase structure 640 through the first isolation portion 6731.

With continued reference to FIG. 8E, the semiconductor layer 631 may be formed on a side of the first stack structure 610 by using a thin film deposition process such as CVD, PVD, ALD, or any combination thereof. For example, the semiconductor layer 631 may be formed within the memory region AR and the connection region CR shown in FIG. IC. For another example, the semiconductor layer 631 may be formed within the memory region AR shown in FIG. IC, and is not formed within the connection region CR. Optionally, the semiconductor layer 631 is located in the connection region CR and can be replaced by an insulation material layer (not shown).

In some implementations, as shown in FIG. 8F, a second stack structure 620 may be formed on a side of the semiconductor layer 631 away from the first stack structure 610, and a second staircase structure 650 may be formed in the second stack structure 620. The second staircase structure 650 may comprise a plurality of second step structures 651 distributed along a circumferential direction. Optionally, the second step structure 651 may comprise a plurality of second sub-step structures 6511 distributed along a radial direction.

In some implementations, as described above, the second stack structure 620 and the second staircase structure 650 may be obtained by replacing a second sacrificial layer in an initial second stack structure and an initial second staircase structure with a second gate layer 622. Thus, the second stack structure 620 and the second staircase structure 650 comprise the second dielectric layer 621 and the second gate layer 622 alternately disposed in the D3 direction.

In some implementations, in the above process of forming the second stack structure 620, another first gate line slit extending through the initial second stack structure and the semiconductor layer 631, and another second gate line slit extending through the initial second stack structure may be first formed, and the second sacrificial layer may be replaced with the second gate layer 622 by using the first gate line slit and/or the second gate line slit. The first gate line slit may correspond to outer contours of portions of the first stack structure 110 and the semiconductor layer 131 through which the first gate line isolation structure 132 extends shown in FIG. 1A. The second gate line slit may be an outer contour of the second gate line isolation portion 1331-2 located in the second stack structure 120 shown in FIG. 1A. For example, the first gate line slit may be at least partially aligned with a portion of the first gate line isolation structure that has been formed in the D3 direction, and the second gate line slit may be at least partially aligned with the second gate line isolation portion that has been formed in the D3 direction. For example, the first gate line slit and the second gate line slit may extend along the D1 direction by means of patterning design, and the second gate line slit may be located between adjacent first gate line slits in the D2 direction. Further, after forming the second stack structure 620, one or more insulation materials may be filled in the above first gate line slit and the second gate line slit, or the first oxide layer is first formed by deposition and then the first polysilicon body is formed by deposition, so that another portion of the first gate line isolation structure and another second gate line isolation portion are respectively formed.

In some implementations, a second insulation structure 672 may be formed on a side of the second staircase structure 650 having a staircase surface by using a thin film deposition process such as CVD, PVD, ALD, or any combination thereof. In other words, the second insulation structure 672 may be formed on a side of the second staircase structure 650 away from the semiconductor layer 631.

In some implementations, a second connection hole 6902 extending through the second insulation structure 672 and the second staircase structure 650 may be formed by using an etching (e.g., dry etching and/or wet etching) process. For example, the second connection hole 6902 may expose the first connection portion 661. Further, portions of the second insulation structure 672 and the second dielectric layer 621 at the periphery of the second connection hole 6902 may be removed by using an etching (e.g., wet etching) process. In other words, portions of the second connection hole 6902 extending through the second insulation structure 672 and the second dielectric layer 621 may be enlarged. After the above process, in a plane perpendicular to the D3 direction, each of a size (e.g., a diameter) of a portion of the second connection hole 6902 extending through the second insulation structure 672 and a size (e.g., a diameter) of a portion of the second connection hole 6902 extending through the second dielectric layer 621 is greater than a size (e.g., a diameter) of a portion of the second connection hole 6902 extending through the second gate layer 622.

In some implementations, the manufacturing method 500 may further comprise an operation of forming the second isolation portion 6732 on a sidewall of a portion of the second staircase structure 650 through which the second connection hole 6902 extends. For example, an initial second isolation portion (not shown) may be formed on a sidewall of the second connection hole 6902 by using a thin film deposition process such as CVD, PVD, ALD, or any combination thereof. For example, the initial second isolation portion may cover a surface of the second gate layer 622 that is the top layer in the second staircase structure 650. Further, a portion of the surface of the second gate layer 622 that is the top layer in the second staircase structure 650 may be removed by using an etching (e.g., dry etching) process. Thus, the second gate layer 622 that is the top layer in the second staircase structure 650 is exposed. Since the size of the portion of the second connection hole 6902 extending through the second insulation structure 672 is greater than the size of the portion of the second connection hole 6902 extending through the second gate layer 622 in the second staircase structure 650 in a plane perpendicular to the D3 direction, in the above etching process, a portion of the initial second isolation portion located on a sidewall of a portion of the second connection hole 6902 extending through the second staircase structure 650 is kept, that is, the remaining unetched initial second isolation portion may be the second isolation portion 6732. The first isolation portion 6731 and the second isolation portion 6732 may be referred to as isolation layer 673. The isolation layer 673 may be formed on sidewalls of portions of the first connection hole 6901 (referring to FIG. 8C) and the second connection hole 6902 extending through the first staircase structure 540 and the second staircase structure 650 respectively.

In some implementations, as shown in FIGS. 8F and 8G, a conductive material may be filled in the second connection hole 6902 with the second isolation portion 6732 formed by using a thin film deposition process such as CVD, PVD, ALD, or any combination thereof, to form the second connection portion 662. The second connection portion 662 may be connected to (e.g., in contact with) the second gate layer 622 that is the top layer in the second staircase structure 650, and electrically isolated from the second gate layer 622 that is not the top layer in the second staircase structure 650 through the second isolation portion 6732. The first connection portion 661 and the second connection portion 662 may be referred to as connection structure 660.

In another implementation, the connection holes extending through the second insulation structure 672, the second staircase structure 650, the first insulation structure 671 and the first staircase structure 640 may be formed in the same process after forming the first stack structure 610 and the second stack structure 620 (or the initial first stack structure 610′ (referring to FIG. 8A) and the initial second stack structure), so that the isolation layers 673 may be formed on sidewalls of portions of the first staircase structure 640 and the second staircase structure 650 through which the above connection holes extend in the same process, and then the connection structure 660 is formed in the connection hole in which the isolation layer 673 is formed. The specific order in which the connection hole, the isolation layer 673 and the connection structure 660 are formed is not limited in the present disclosure.

After the above process, the connection structure 660 may be connected to one first step structure 641 (or the first sub-step structure 6411) and one second step structure 651 (or the second sub-step structure 6511).

In some implementations, the manufacturing method 500 may further comprise: forming a first bit line structure on a side of the first stack structure 610 away from the semiconductor layer 631. The first bit line structure comprises a plurality of first bit line portions distributed in a D2 direction. The first bit line portion extends along the D2 direction and is located between the first gate line isolation structure and the second gate line isolation structure, or between adjacent second gate line isolation structures; and a first isolation structure is formed between adjacent first bit line portions. For example, the first isolation structure may be first formed on a side of the first stack structure 610 away from the semiconductor layer 631, and then the first bit line structure extending through the first isolation structure may be formed. The number and positions of the first bit line portions included in the first bit line structure may be implemented by means of patterning design in the forming process.

In some implementations, the manufacturing method 500 may further comprise: forming a second bit line structure on a side of the second stack structure 620 away from the semiconductor layer 631. The second bit line structure comprises a plurality of second bit line portions distributed in the D2 direction. The second bit line portion extends along the D2 direction and is located between the first gate line isolation structure and the second gate line isolation structure, or between adjacent second gate line isolation structures; and a second isolation structure is formed between adjacent second bit line portions. For example, the second isolation structure may be first formed on a side of the second stack structure 620 away from the semiconductor layer 631, and then the second bit line structure extending through the second isolation structure may be formed. The number and positions of the second bit line portions included in the second bit line structure may be implemented by means of patterning design in the forming process.

In some implementations, the manufacturing method 500 may further comprise the following operation: forming a first channel structure extending through the second stack structure 620, the semiconductor layer 631, and the first stack structure 610. The first channel structure is connected to the first bit line portion and the second bit line portion.

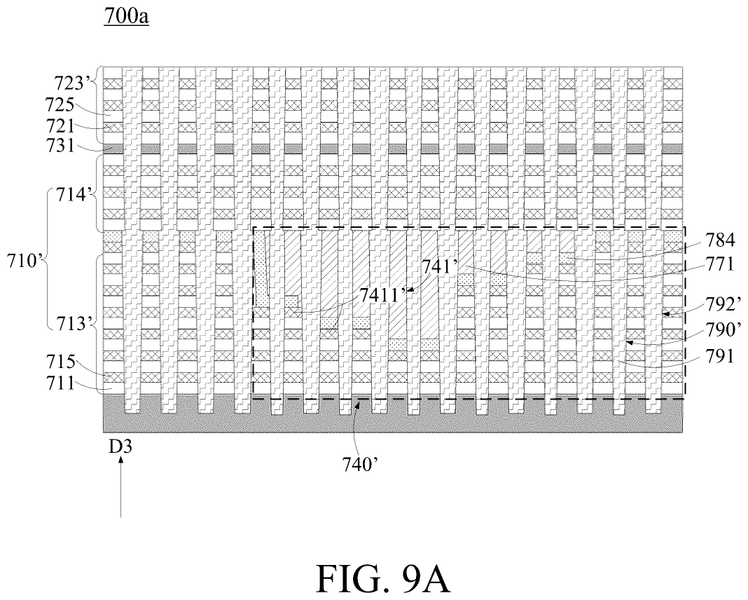

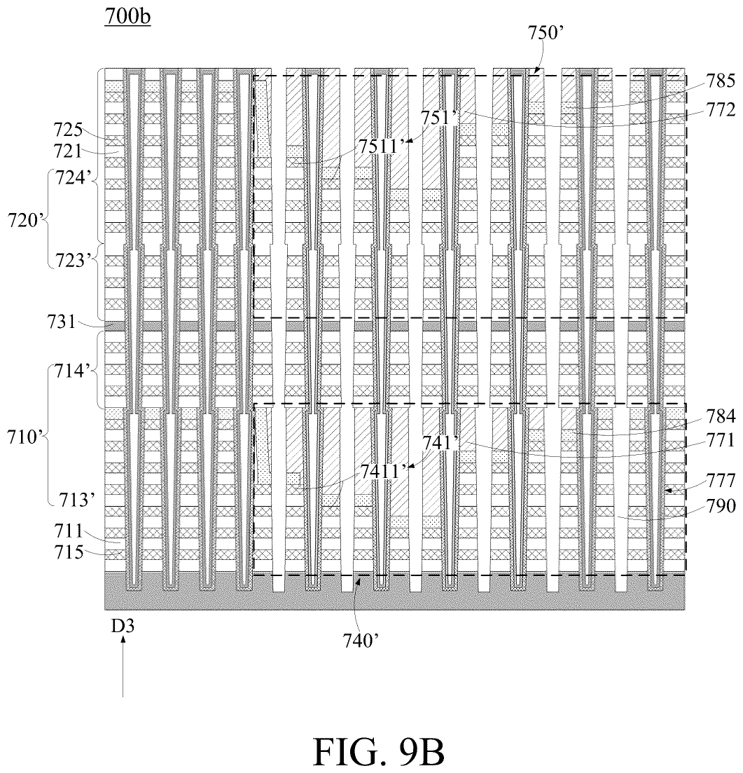

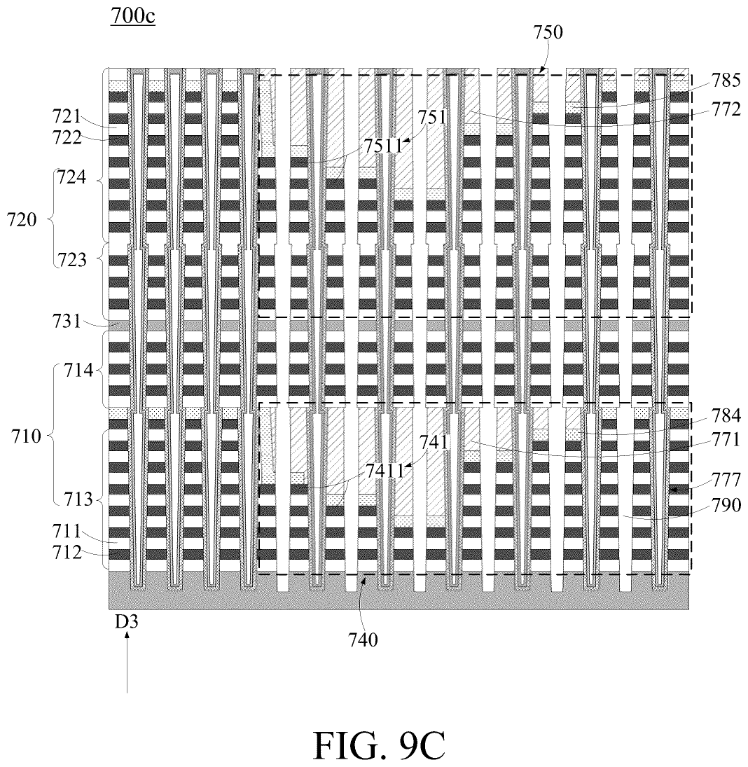

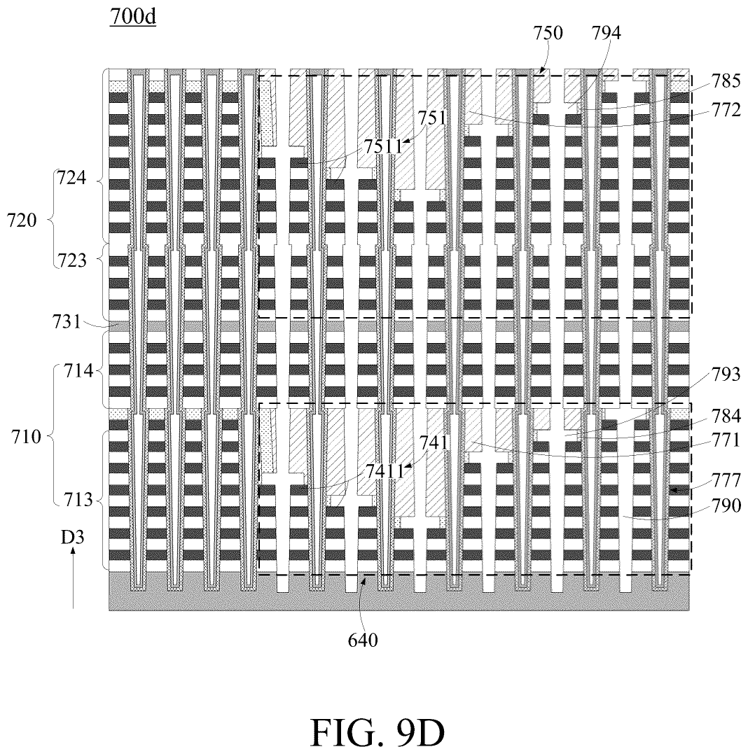

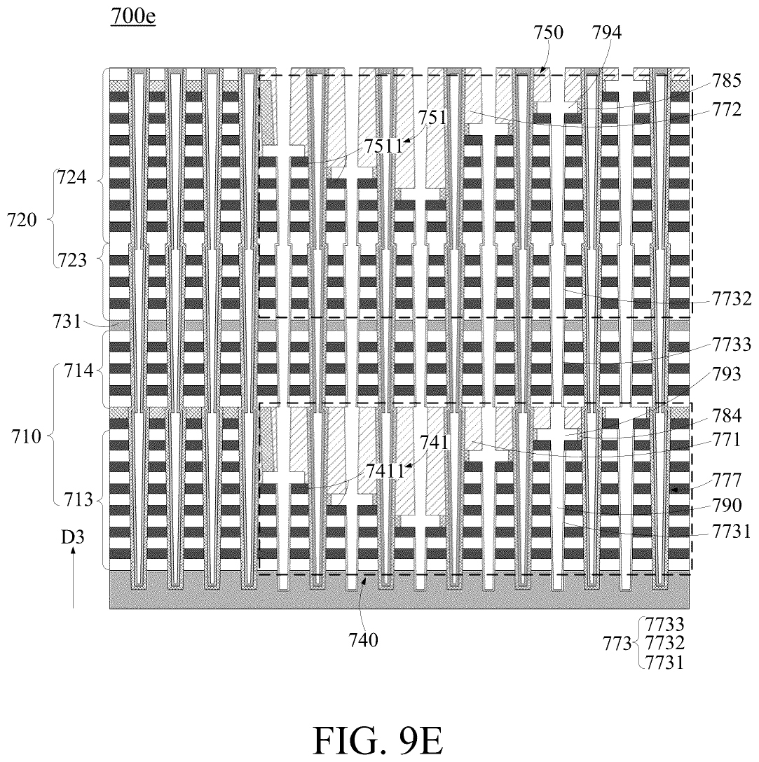

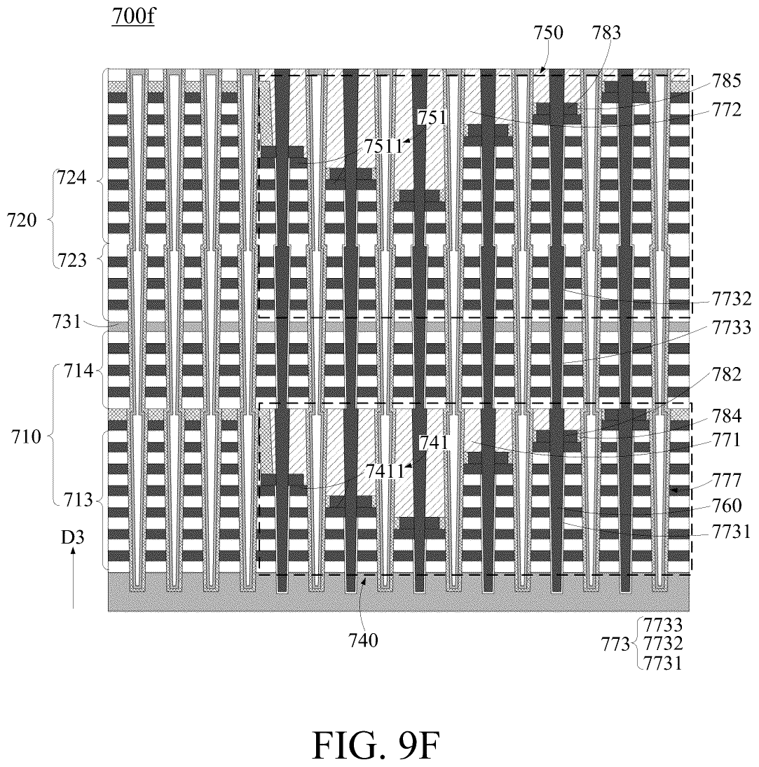

FIG. 9A to FIG. 9F are schematic cross-sectional views of a semiconductor structure in a manufacturing process provided by another example of the present disclosure. FIG. 9A illustrates an intermediate structure 700a after forming an initial first stack structure 710′, an initial first staircase structure 740′, and an initial connection hole 790′. FIG. 9B illustrates an intermediate structure 700b after forming a semiconductor layer 731, an initial second stack structure 720′, an initial second staircase structure 750′, and a connection hole 790. FIG. 9C illustrates an intermediate structure 700c after forming a first stack structure 710, a first staircase structure 740, a second stack structure 720, and a second staircase structure 750. FIG. 9D illustrates an intermediate structure 700d after forming a first annular groove 793 and a second annular groove 794. FIG. 9E illustrates an intermediate structure 700e after forming an isolation layer 773. FIG. 9F illustrates an intermediate structure 700f after forming a connection structure 760.

The manufacturing method 500 comprising the operations S510 to S540 is exemplarily described below in conjunction with FIGS. 9A to 9F. For the purpose of brevity, in this example, the same content as the previous example are not described herein again.

In some implementations, as shown in FIG. 9A, an initial first stack portion 713′ may be first formed, and the initial first staircase structure 740′ may be formed in the initial first stack portion 713′. The initial first stack portion 713′ and the initial first staircase structure 740′ may each comprise a first dielectric layer 711 and a first sacrificial layer 715 alternately disposed in the D3 direction. The initial first staircase structure 740′ may comprise a plurality of initial first step structures 741′ distributed along a circumferential direction. Optionally, the initial first step structure 741′ may comprise a plurality of initial first sub-step structures 7411′ distributed along a radial direction. For example, the top layer of each initial first step structure 741′ (or each initial first sub-step structure 7411′) is the first sacrificial layer 715.

Next, a first insulation layer 784 covering a surface of the initial first staircase structure 740′ may be formed. Then, a first insulation structure 771 may be formed on a side of the first insulation layer 784 away from the initial first staircase structure 740′. Thus, the first insulation layer 784 may be formed between the initial first staircase structure 740′ and the first insulation structure 771. For example, the first insulation layer 784 is in contact with the first sacrificial layer 715 that is the top layer of each initial first step structure 741′ (or each initial first sub-step structure 7411′).

Further, an initial second stack portion 714′ covering the initial first stack portion 713′ and the first insulation structure 771 may be formed, and the semiconductor layer 731 and an initial third stack portion 723′ are sequentially formed on a side of the initial second stack portion 714′ away from the initial first stack portion 713′. The initial second stack portion 714′ may comprise the first dielectric layer 711 and the first sacrificial layer 715 alternately disposed in the D3 direction. The initial first stack portion 713′ and the initial second stack portion 714′ may constitute the initial first stack structure 710′. The initial third stack portion 723′ may comprise second dielectric layers 721 and second sacrificial layers 725 alternately disposed in the D3 direction. The initial third stack portion 723′ may be a portion of the initial second stack structure 720′ (referring to FIG. 9B).

It should be noted that the semiconductor layer 731 may be formed within the memory region AR and the connection region CR shown in FIG. 1C. As another option, the semiconductor layer 731 may be formed within the memory region AR shown in FIG. IC and not within the connection region CR. Optionally, the semiconductor layer 731 is located within the connection region CR and can be replaced by an insulation material layer (not shown).

In some implementations, an initial connection hole 790′ sequentially extending through the initial third stack portion 723′, the semiconductor layer 731 (or the insulation material layer), the initial second stack portion 714′, the first insulation structure 771, and the initial first staircase structure 740′ may be formed. Optionally, an initial second channel hole 792′ sequentially extending through the initial third stack portion 723′, the semiconductor layer 731 (or the insulation material layer), the initial second stack portion 714′, the first insulation structure 771, and the initial first staircase structure 740′ may be formed. Then, a sacrificial material 791 may be filled in the initial connection hole 790′ and an initial second channel hole 692′.

In other implementations, the initial connection hole 790′ and the initial second channel hole 792′ and the sacrificial material 791 filled in the initial connection hole 790′ and the initial second channel hole 792′ may be implemented by step-wise etching and filling. For example, a first etching and filling process may be performed to form the initial connection hole 790′ and a portion of the sacrificial material 791 located therein after forming the initial first stack portion 713′, the initial first staircase structure 740′, and the first insulation structure 771. Next, after the initial second stack portion 714′, the semiconductor layer 731, and the initial third stack portion 723′ are formed, a second etching and filling process is performed to form a complete initial connection hole 790′ and the sacrificial material 791 located therein after forming the initial second stack portion 714′, the semiconductor layer 731, and the initial third stack portion 723′.

In some implementations, as shown in FIG. 9B, an initial fourth stack portion 724′ may be formed on a side of the initial third stack portion 723′ away from the semiconductor layer 731. The initial fourth stack portion 724′ may comprise second dielectric layers 721 and second sacrificial layers 725 alternately formed in the D3 direction. The initial third stack portion 723′ and the initial fourth stack portion 724′ may constitute the initial second stack structure 720′.

In some implementations, the initial second staircase structure 750′ may be formed in the initial second stack structure 720′. The initial second staircase structure 750′ may comprise a plurality of initial second step structures 751′ distributed along a circumferential direction. Optionally, the initial second step structure 751′ may comprise a plurality of initial second sub-step structures 7511′ distributed along a radial direction. For example, the top layer of each initial second step structure 751′ (or each initial second sub-step structure 7511′) is the second sacrificial layer 725.

Next, a second insulation layer 785 covering a surface of the initial second staircase structure 750′ may be formed. Then, a second insulation structure 772 may be formed on a side of the second insulation layer 785 away from the initial second staircase structure 750′. Thus, the second insulation layer 685 may be formed between the initial second staircase structure 750′ and the second insulation structure 772. For example, the second insulation layer 785 is in contact with the second sacrificial layer 725 that is the top layer of each initial second step structure 751′ (or each initial second sub-step structure 7511′).

In some implementations, a via sequentially extending through the second insulation structure 772 and the initial second staircase structure 750′ and, for example, exposing the sacrificial material 791 in the initial connection hole 790′ may be formed. The via and the initial connection hole 790′ may be referred to as connection hole 790. Next, the sacrificial material 791 in the connection hole 690 may be removed.

In some implementations, another via sequentially extending through the second insulation structure 772 and the initial second staircase structure 750′ and, for example, exposing the sacrificial material 791 in the initial second channel hole 792′ may be formed. This via and the initial second channel hole 692′ may be referred to as a second channel hole (corresponding to an outer contour of a second channel structure 777). Next, the sacrificial material 791 in the second channel hole may be removed, and the second channel structure 777 may be formed in the second channel hole.

In some implementations, as shown in FIGS. 9B and 9C, the first sacrificial layer 715 may be replaced with the first gate layer 712, and the second sacrificial layer 725 may be replaced with the second gate layer 722. The initial first stack structure 710′, the initial first staircase structure 740′, the initial second stack structure 720′, and the initial second staircase structure 750′ are respectively converted into the first stack structure 710, the first staircase structure 740, the second stack structure 720, and the second staircase structure 750. For example, the first insulation layer 784 may be in contact with the first gate layer 712 that is the top layer of each first step structure 741 (or each first sub-step structure 7411). The second insulation layer 785 may be in contact with the second gate layer 722 that is the top layer of each second step structure 751 (or each second sub-step structure 7511). The connection hole 790 may extend through the first insulation layer 784 and the second insulation layer 785. In the above replacement process, the second channel structure 777 may be configured to provide mechanical support.

In some implementations, in the above process of forming the first stack structure 710 and the second stack structure 720, a first gate line slit extending through the initial second stack structure 720′, the semiconductor layer 731, and the initial first stack structure 710′, and a second gate line slit extending through the initial second stack structure 720′, the semiconductor layer 731, and the initial first stack structure 710′ may be first formed. Next, the first sacrificial layer 715 is replaced with the first gate layer 712 and the second sacrificial layer 725 is replaced with the second gate layer 722 by using the first gate line slit and/or the second gate line slit. The first gate line slit may correspond to an outer contour of the first gate line isolation structure 432 shown in FIG. 6A. The second gate line slit may be an outer contour of the second gate line isolation structure 433 shown in FIG. 6A. For example, the first gate line slit and the second gate line slit may extend along the D1 direction by means of patterning design, and the second gate line slit may be located between adjacent first gate line slits in the D2 direction. Further, after forming the first stack structure 710 and the second stack structure 720, one or more insulation materials may be filled in the first gate line slit and the second gate line slit, or a second oxide layer is first formed by deposition and then a second polysilicon body is formed by deposition, so that the first gate line isolation structure and the second gate line isolation structure are respectively formed.

In some implementations, as shown in FIG. 9D, an etching (e.g., wet etching) process may be used to remove a portion of the first insulation layer 784 at the periphery of the connection hole 790 to form the first annular groove 793, and remove a portion of the second insulation layer 785 at the periphery of the connection hole 790 to form the second annular groove 794. The first annular groove 793, the second annular groove 794, and the contact hole 790 are communicated with one another. The first annular groove 793 may expose the first gate layer 712 that is the top layer of each first step structure 741 (or each first sub-step structure 7411). The second annular groove 794 may expose the second gate layer 722 that is the top layer of each second step structure 751 (or each second sub-step structure 7511).

In some implementations, as shown in FIGS. 9D and 9E, initial isolation layers (not shown) may be formed on inner walls of the connection hole 790 and the first annular groove 793 and the second annular groove 794 by using a thin film deposition process such as CVD, PVD, ALD, or any combination thereof. Then, portions of the initial isolation layers on the inner walls of the first annular groove 793 and the second annular groove 794 may be removed by an etching process. Since a size of the first annular groove 793 and a size of the second annular groove 794 are greater than a size of a portion of the connection hole 790 extending through the first staircase structure 740, a size of a portion of the connection hole 790 extending through the second staircase structure 750, and a size of a portion of the connection hole 790 extending through the second stack portion 714 in a plane perpendicular to the D3 direction, in the above etching process, portions of the initial isolation layer located on sidewalls of the portions of the connection hole 790 extending through the first staircase structure 740, the second staircase structure 750, and the second stack portion 714 are kept, that is, the remaining unetched initial isolation layers may be the isolation layer 773. The portion of the isolation layer 773 located on the sidewall of the portion of the connection hole 790 extending through the first staircase structure 740 may be a first isolation portion 7731, the portion of the isolation layer 773 located on the sidewall of the portion of the connection hole 790 extending through the second staircase structure 750 may be a second isolation portion 7732, and the portion of the isolation layer 773 located on the sidewall of the portion of the connection hole 790 extending through the second stack portion 714 may be a third isolation portion 7733.

In some implementations, as shown in FIGS. 9E and 9F, a conductive material may be filled in the connection hole 790, the first annular groove 793, and the second annular groove 794 by using a thin film deposition process such as CVD, PVD, ALD, or any combination thereof. A portion of the conductive material filled in the connection hole 790 may be a connection structure 760, a portion of the conductive material filled in the first annular groove 793 may be a first surrounding portion 782, and a portion of the conductive material filled in the second annular groove 794 may be a second surrounding portion 783. For example, the connection structure 760, the first surrounding portion 782, and the second surrounding portion 783 may be an integrated structure.

After the above process, the connection structure 760 may be connected to one first step structure 741 (or the first sub-step structure 7411) through the first surrounding portion 782, and connected to one second step structure 751 (or the second sub-step structure 7511) through the second surrounding portion 783. For example, the first surrounding portion 782 may be in contact with the first gate layer 712 that is the top layer in one first step structure 741 (or the first sub-step structure 7411), and the second surrounding portion 783 may be in contact with the second gate layer 722 that is the top layer in one second step structure 751 (or the second sub-step structure 7511).

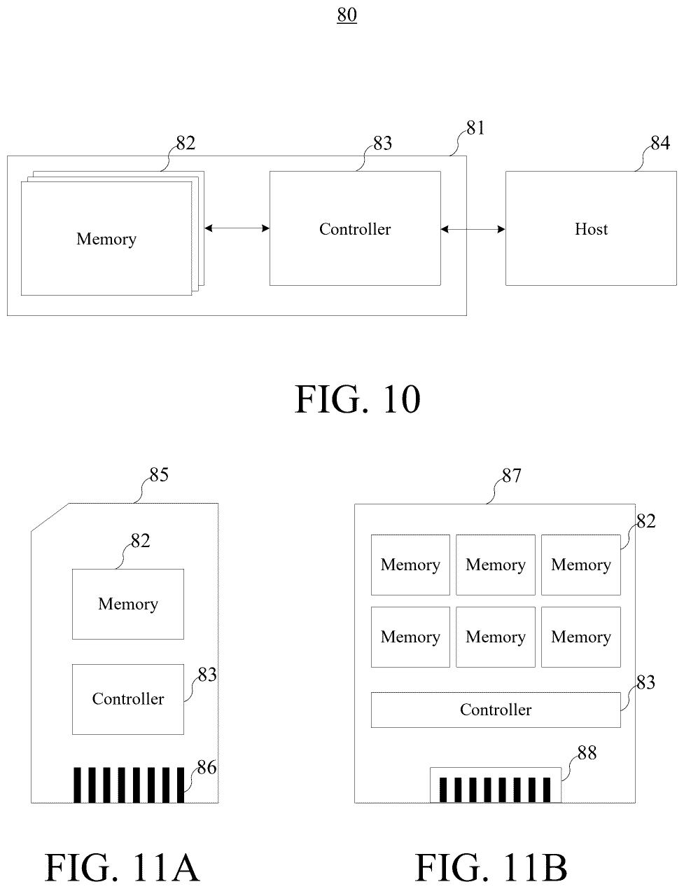

An example of the present disclosure further provides a memory system. FIG. 10 is a schematic block diagram of a system having a memory system provided by an example of the present disclosure. FIG. 11A and FIG. 11B are schematic block diagrams of a memory system provided by an example of the present disclosure.

As shown in FIG. 10, a system 80 may be a mobile phone, a desktop computer, a laptop computer, a tablet computer, a vehicle computer, a game console, a printer, a positioning device, a wearable electronic device, a smart sensor, a virtual reality (VR) device, an augmented reality (AR) device, or any other suitable electronic device (which has a memory system 81 therein). As shown in FIG. 10, the system 80 may comprise a host 84 and the memory system 81 having one or more memories 82 and a controller 83. The host 84 may be a processor of an electronic device, such as a central processing unit (CPU), or may be a system-on-chip (SoC), such as an application processor (AP). The host 84 may be configured to send or receive data to and from the memory 82.

The memory 82 may comprise the semiconductor structure described in any implementation of the present disclosure, such as the semiconductor structure 100 shown in FIG. 1A to FIG. 2C, the semiconductor structure 200 shown in FIG. 4, and the semiconductor structure 300 shown in FIG. 5. According to some implementations, the controller 83 is coupled to the memory 82 and the host 84 and is configured to control the memory 82. The controller 83 may manage data stored in the memory 82 and communicate with the host 84. In some implementations, the controller 83 is designed to operate in a low duty cycle environment like a secure digital (SD) card, compact flash (CF) card, universal serial bus (USB) flash drive, or other medium used in electronic devices such as personal computers, digital cameras, mobile phones, etc. In some implementations, the controller 83 is designed for operating in a high duty cycle environment like an SSD or embedded multi-media-card (eMMC) functioning as data storage for a mobile device, such as a smartphone, a tablet computer, a laptop computer, etc, and an enterprise storage array. The controller 83 may be configured to control operations of the memory 82, such as read, erase, and program operations. The controller 83 may further be configured to manage various functions with respect to data stored or to be stored in the memory 82, including, but not limited to, bad block management, garbage collection, logical-to-physical address translation, wear leveling, etc. In some implementations, the controller 83 is further configured to process error correction codes (ECC) with respect to data read from or written to the memory 82. Other suitable functions may also be performed by the controller 83, such as formatting the memory 82. The controller 83 may communicate with an external device (e.g., host 84) according to a particular communication protocol. For example, the controller 83 may communicate with the external device through at least one of various interface protocols, such as a USB protocol, an MMC protocol, a Peripheral Component Interconnect (PCI) protocol, a PCI-express (PCI-E) protocol, an Advanced Technology Attachment (ATA) protocol, a Serial ATA protocol, a Parallel ATA protocol, a Small Computer Small Interface (SCSI) protocol, an Enhanced Small Disk Interface (ESDI) protocol, an Integrated Drive Electronics (IDE) protocol, a Firewire protocol, or the like.

The controller 83 and the one or more memories 82 may be integrated into various types of memory systems, e.g., included in the same package, such as a Universal Flash memory (UFS) package or an eMMC package. That is, the memory system 81 may be implemented and packaged into different types of end electronic products. In one example as shown in FIG. 11A, the controller 83 and the single memory 82 may be integrated into the memory card 85. The memory card 85 may comprise a PC Card (PCMCIA, Personal Computer Memory Card International Association), a CF card, a smart media (SM) card, a memory stick, a multimedia card (MMC, RS-MMC, MMCmicro), an SD card (SD, miniSD, microSD, SDHC), UFS, etc. The memory card 85 may further comprise a memory card connector 86 coupling the memory card 85 to a host (e.g., the host 84 in FIG. 10). In another example as shown in FIG. 11B, the controller 83 and multiple memories 82 may be integrated into SSD 87. SSD 87 may further comprise an SSD connector 88 coupling SSD 87 to a host (e.g., host 84 in FIG. 10). In some implementations, the memory capacity and/or operating speed of SSD 87 is higher than the memory capacity and/or operating speed of the memory card 85.

The above description is only an implementation of the present disclosure and an explanation of the applied technical principles. It should be understood by those skilled in the art that the protection scope involved in the present disclosure is not limited to the technical solutions of the specific combination of the above technical features, and should also cover other technical solutions formed by any combination of the above technical features or their equivalent features without departing from the technical concept. For example, the technical solutions formed by replacing the above features with the technical features with similar functions disclosed in the present disclosure (but not limited to).

What is claimed is:

1. A semiconductor structure, comprising:
a first stack structure;
a second stack structure located on a side of the first stack structure;
a semiconductor layer located between the first stack structure and the second stack structure;
first gate line isolation structures extending through the second stack structure, the semiconductor layer, and the first stack structure along a stacking direction of the first stack structure and the second stack structure, wherein the first gate line isolation structures extend along a first direction; and
second gate line isolation structures extending through the second stack structure and the first stack structure along the stacking direction and extending along the first direction, wherein the second gate line isolation structure is located between adjacent ones of the first gate line isolation structures in a second direction intersecting with the first direction.

2. The semiconductor structure of claim 1, wherein, in the first direction, a size of the first gate line isolation structure is greater than a size of the second gate line isolation structure.

3. The semiconductor structure of claim 1, further comprising:
a first bit line structure located on a side of the first stack structure away from the semiconductor layer and comprising a plurality of first bit line portions distributed in the second direction, wherein a first bit line portion extends along the second direction and is located between the first gate line isolation structure and the second gate line isolation structure or between first adjacent ones of the second gate line isolation structures;
a first isolation structure located between adjacent ones of the plurality of first bit line portions;
a second bit line structure located on a side of the second stack structure away from the semiconductor layer and comprising a plurality of second bit line portions distributed in the second direction, wherein a second bit line portion extends along the second direction and is located between the first gate line isolation structure and the second gate line isolation structure or between second adjacent ones of the second gate line isolation structures; and
a second isolation structure located between adjacent ones of the plurality of second bit line portions.

4. The semiconductor structure of claim 3, wherein the semiconductor layer extends between corresponding adjacent ones of the first gate line isolation structures.

5. The semiconductor structure of claim 1, wherein the second gate line isolation structure extends through the semiconductor layer.

6. The semiconductor structure of claim 1, wherein, in a plane defined by the first direction and the second direction, the first stack structure and the second stack structure comprise a memory region and a connection region, and the connection region is located on a side of the memory region in the first direction, and
wherein the first gate line isolation structure extends within the memory region and the connection region, and the second gate line isolation structure extends within the memory region.

7. The semiconductor structure of claim 1, further comprising:
a first staircase structure located in the first stack structure, the first staircase structure comprising a plurality of first step structures distributed along a first circumferential direction; and
a second staircase structure located in the second stack structure, the second staircase structure comprising a plurality of second step structures distributed along a second circumferential direction.

8. The semiconductor structure of claim 7, wherein the first step structure comprises a plurality of first sub-step structures distributed along a first radial direction; and
wherein the second step structure comprises a plurality of second sub-step structures distributed along a second radial direction.

9. The semiconductor structure of claim 8, wherein depths of the plurality of first sub-step structures relative to the semiconductor layer are different from each other, and depths of the plurality of second sub-step structures relative to the semiconductor layer are different from each other.

10. The semiconductor structure of claim 7, wherein, in a plane defined by the first direction and the second direction, the first staircase structure comprises a plurality of first step regions distributed along a first circumferential direction, the first step structure is located within adjacent ones of the first step regions, the second staircase structure comprises a plurality of second step regions distributed along a second circumferential direction, and the second step structure is located within adjacent ones of the second step regions, and
wherein a shape of the first step region comprises a first sector, and a shape of the second step region comprises a second sector.

11. The semiconductor structure of claim 7, wherein the first staircase structure and the second staircase structure are at least partially aligned in the stacking direction of the first stack structure and the second stack structure.

12. The semiconductor structure of claim 8, further comprising:
a connection structure extending along the stacking direction of the first stack structure and the second stack structure and being connected to one of the first sub-step structures and one of the second sub-step structures.

13. The semiconductor structure of claim 12, further comprising:
a first insulation structure located on a side of the first staircase structure close to the semiconductor layer; and
a second insulation structure located on a side of the second staircase structure away from the semiconductor layer,
wherein the connection structure extends through the second insulation structure, the second staircase structure, the first insulation structure and the first staircase structure.

14. The semiconductor structure of claim 13, further comprising:
an isolation layer surrounding portions of the connection structure that extend through the first staircase structure and the second staircase structure.

15. The semiconductor structure of claim 13, wherein:
in a plane defined by the first direction and the second direction, a size of a portion of the connection structure extending through the first insulation structure is greater than a size of a portion of the connection structure extending through the first staircase structure, and
in the plane defined by the first direction and the second direction, a size of a portion of the connection structure extending through the second insulation structure is greater than a size of a portion of the connection structure extending through the second staircase structure.

16. A memory system, comprising:
a memory comprising:
a semiconductor structure comprising:
a first stack structure;
a second stack structure located on a side of the first stack structure;
a semiconductor layer located between the first stack structure and the second stack structure;
first gate line isolation structures extending through the second stack structure, the semiconductor layer, and the first stack structure along a stacking direction of the first stack structure and the second stack structure and extending along a first direction; and
second gate line isolation structures extending through the second stack structure and the first stack structure along the stacking direction and extending along the first direction, wherein the second gate line isolation structure is located between adjacent ones of the first gate line isolation structures in a second direction intersecting with the first direction; and
a controller coupled to the memory and configured to control the memory.

17. A manufacturing method of a semiconductor structure, comprising:
forming a semiconductor layer on a side of a first stack structure;
forming a second stack structure on a side of the semiconductor layer away from the first stack structure;
forming first gate line isolation structures extending through the second stack structure, the semiconductor layer, and the first stack structure along a stacking direction of the first stack structure and the second stack structure; and
forming second gate line isolation structures extending through the first stack structure and the second stack structure along the stacking direction,
wherein the first gate line isolation structure and the second gate line isolation structure extend along a first direction, and the second gate line isolation structure is located between adjacent ones of the first gate line isolation structures in a second direction intersecting with the first direction.

18. The manufacturing method of claim 17, further comprising:
forming a first bit line structure on a side of the first stack structure away from the semiconductor layer, wherein the first bit line structure comprises a plurality of first bit line portions distributed in the second direction, wherein the first bit line portion extends along the second direction and is located between the first gate line isolation structure and the second gate line isolation structure or between adjacent ones of the second gate line isolation structures;
forming a first isolation structure between adjacent ones of the first bit line portions;
forming a second bit line structure on a side of the second stack structure away from the semiconductor layer, wherein the second bit line structure comprises a plurality of second bit line portions distributed in the second direction, wherein the second bit line portion extends along the second direction and is located between the first gate line isolation structure and the second gate line isolation structure or between adjacent ones of the second gate line isolation structures; and
forming a second isolation structure between adjacent ones of the second bit line portions.

19. The manufacturing method of claim 17, wherein forming the second gate line isolation structures extending through the first stack structure and the second stack structure along the stacking direction comprises:
forming the second gate line isolation structures extending through the second stack structure, the semiconductor layer, and the first stack structure along the stacking direction.

20. The manufacturing method of claim 17, further comprising:
forming a first staircase structure in the first stack structure, wherein the first staircase structure comprises a plurality of first step structures distributed along a first circumferential direction; and
forming a second staircase structure in the second stack structure, wherein the second staircase structure comprises a plurality of second step structures distributed along a second circumferential direction.
